(19) United States
(12) Patent Application Publication
(10) Pub. No.: US 2026/0101797 A1
(43) Pub. Date: Apr. 9, 2026

(54) SEMICONDUCTOR PACKAGE

(71) Applicant: SAMSUNG ELECTRONICS CO., LTD., Suwon-si (KR)

(72) Inventors: JEONGGI JIN, Suwon-si (KR); UN-BYOUNG KANG, Suwon-si (KR); JIYOUNG PARK, Suwon-si (KR); JUNHYUN AN, Suwon-si (KR)

(21) Appl. No.: 19/178,647

(22) Filed: Apr. 14, 2025

(30) Foreign Application Priority Data
Oct. 7, 2024 (KR) 10-2024-0136097

(51) Int. Cl. H01L 23/49; H01L 23/31; H01L 23/498; H01L 25/04

(52) U.S. Cl. CPC H10W 72/50; H10W 74/111; H10W 90/00; H10W 90/701; H10W 90/24

(57) ABSTRACT

A semiconductor package includes a package substrate, a first semiconductor chip on the package substrate, a molding layer surrounding the first semiconductor chip on the package substrate, a conductive post extending through the molding layer on one side of the first semiconductor chip and connected to the package substrate, and external terminals on a lower surface of the package substrate. The conductive post includes a first post, and a second post on the first post, and connected to a first upper surface of the first post. The first post has a columnar shape, and the second post has a tapered shape in which a width thereof decreases toward the first post.

### CROSS-REFERENCE TO RELATED APPLICATIONS

This U.S. non-provisional patent application claims priority under 35 U.S.C. § 119 to Korean Patent Application No. 10-2024-0136097, filed on Oct. 7, 2024, the entire contents of which are hereby incorporated by reference.

### BACKGROUND

The present disclosure herein relates generally to semiconductor packages, and more particularly, to fan-out packages.

With development of the electronics industry, demand for high-performance, high-speed, and miniaturization of an electronic component is increasing. In response to this trend, recent packaging technology is moving in a direction in which a plurality of semiconductor chips are mounted in one package.

A semiconductor package is an integrated circuit chip implemented in a form suitable for using in an electronic product. In general, the semiconductor package is manufactured by mounting the semiconductor chip on a printed circuit board (PCB), and electrically connecting the same by using a bonding wire or bump. As the electronics industry has evolved, the semiconductor package is evolving in various areas such as miniaturization, weight reduction, and reduction of manufacturing cost. In addition, as an application field thereof expands to a large-capacity storage means, or the like, various types of semiconductor packages are appearing.

As the semiconductor chip becomes highly integrated, a size of the semiconductor chip is gradually decreasing. However, as the semiconductor chip becomes smaller, it becomes more difficult to attach a desired number of solder balls, and to handle and test a solder ball. In addition, there is a limitation of having to diversify the board on which the semiconductor chip is mounted depending on the size of the semiconductor chip. In order to solve this, a fan-out package is suggested.

### SUMMARY OF THE INVENTION

The present disclosure provides a miniaturized semiconductor package with improved integration.

An embodiment of the inventive concept provides a semiconductor package including a package substrate, a first semiconductor chip on the package substrate, a molding layer surrounding the first semiconductor chip on the package substrate, a conductive post extending through the molding layer on one side of the first semiconductor chip and connected to the package substrate, and external terminals on a lower surface of the package substrate, wherein the conductive post includes a first post, and a second past on the first post, and connected to a first upper surface of the first post, the first post has a columnar shape, and the second post has a tapered shape in which a width thereof decreases toward the first post.

In an embodiment of the inventive concept, a semiconductor package includes a first semiconductor chip, a molding layer surrounding the first semiconductor chip, a first conductive post extending through the molding layer on one side of the first semiconductor chip, and a substrate on the molding layer and the first semiconductor chip, wherein the first conductive post includes a first post, a second post on the first post, and in contact with a first upper surface of the first post, and a first seed layer on a first lower surface of the first post, and the second post has a tapered shape in which a width thereof decreases toward the first post.

In an embodiment of the inventive concept, a semiconductor package includes a semiconductor chip, a molding layer surrounding the semiconductor chip, a conductive post extending through the molding layer on one side of the semiconductor chip, and a substrate on the molding layer and the semiconductor chip, and having a substrate wiring pattern connected to the conductive post and the semiconductor chip, wherein the conductive post includes a first post, a seed layer on a lower surface and an outer circumferential surface of the first post, and a second post on the first post, and in contact with a first upper surface of the first post, a width of the first post is greater than a width of the second post on a contact surface of the first post and the second post, a width of a lower surface of the second post is smaller than a width of an upper surface of the second post, and an outer circumferential surface of the second post is in contact with the molding layer.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view for describing a semiconductor package according to embodiments of the inventive concept;

FIGS. 2 and 3 are enlarged diagrams illustrating region A of FIG. 1;

FIG. 4 is a cross-sectional view for describing a semiconductor package according to embodiments of the inventive concept;

FIGS. 5 and 6 are enlarged diagrams illustrating region B of FIG. 4;

FIGS. 7 to 15 are cross-sectional views for describing a semiconductor package according to embodiments of the inventive concept; and

FIGS. 16 to 37 are cross-sectional views for describing a method for manufacturing a semiconductor package according to embodiments of the inventive concept.

### DETAILED DESCRIPTION

A semiconductor package according to the inventive concept will be described with reference to the drawings.

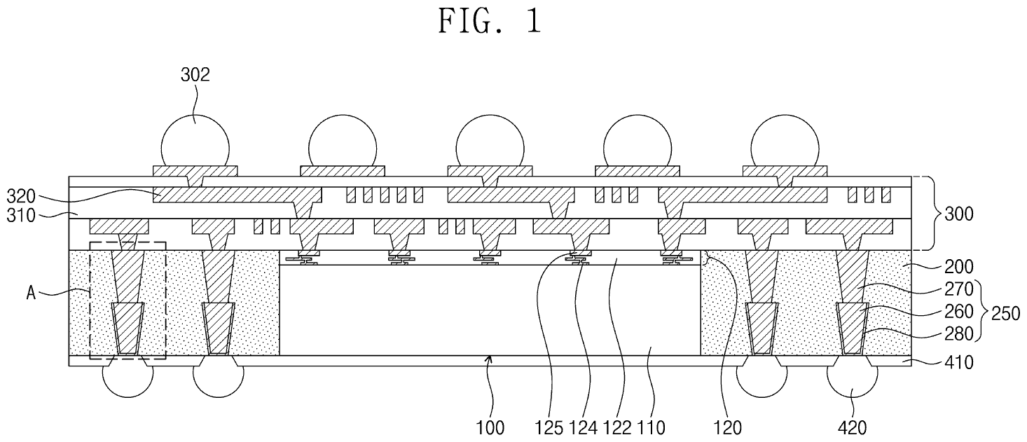

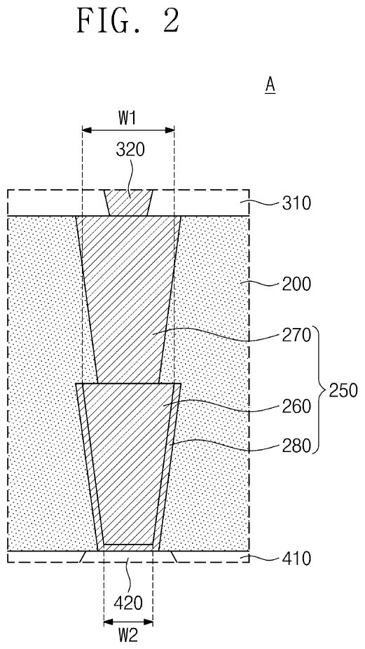

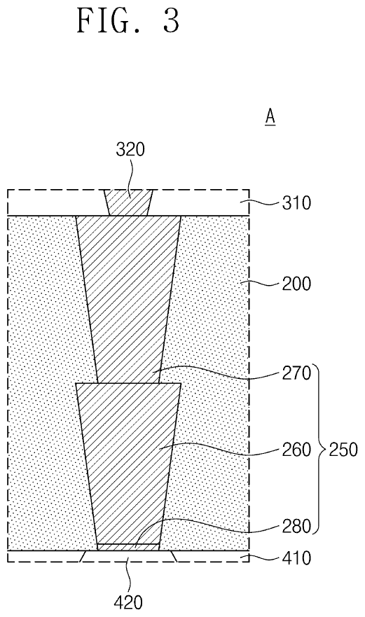

FIG. 1 is a cross-sectional view for describing the semiconductor package according to embodiments of the inventive concept. FIGS. 2 and 3 are enlarged diagrams illustrating region A of FIG. 1.

Referring to FIG. 1, a semiconductor chip 100 may be disposed. The semiconductor chip 100 may be a logic chip. Alternatively, the semiconductor chip 100 may be a memory chip such as DRAM, SRAM, MRAM, or a flash memory. The semiconductor chip 100 may have a front surface and a rear surface. Hereinafter, in the present specification, the front surface may be defined as one surface of an active surface of an integrated element in a semiconductor chip, that is, a surface on which pads of the semiconductor chip are formed, and the rear surface may be defined as an opposite surface opposed to the front surface. An upper surface of the semiconductor chip 100 may be the front surface of the semiconductor chip 100. That is, the semiconductor chip 100 may be disposed in a face-up form. The semiconductor chip 100 may include a chip base layer 110 and a chip circuit layer 120 provided on the front surface of the chip base layer 110.

The chip base layer 110 may include silicon (Si). An integrated element or integrated circuits may be formed on the chip base layer 110.

The chip circuit layer 120 may be provided on an upper or front surface of the chip base layer 110. The chip circuit layer 120 may be electrically connected to the integrated element or the integrated circuits formed in the chip base layer 110. For example, the chip circuit layer 120 may have a chip circuit insulating pattern 122 and a chip circuit pattern 124 provided in the chip circuit insulating pattern 122, and the chip circuit pattern 124 may be connected to the integrated element or the integrated circuits formed in the chip base layer 110. A portion of the chip circuit pattern 124 may be exposed at an upper surface of the chip circuit layer 120, and the exposed portion 125 of the chip circuit pattern 124 may correspond to chip pads 125 of the semiconductor chip 100. The upper surface of the semiconductor chip 100 on which the chip circuit layer 120 is provided may be an active surface of the semiconductor chip 100.

A molding layer 200 may be provided. The molding layer 200 may surround the semiconductor chip 100 on a plan view. The molding layer 200 may cover side surfaces of the semiconductor chip 100. The molding layer 200 may not cover the upper surface and a lower surface of the semiconductor chip 100. More specifically, an upper surface of the molding layer 200 may be substantially flatly coplanar with the upper surface of the semiconductor chip 100. Here, the upper surface of the semiconductor chip 100 may correspond to the upper surface of the chip circuit layer 120 of the semiconductor chip 100. A lower surface of the molding layer 200 may be substantially flatly coplanar with the lower surface of the semiconductor chip 100. Here, the lower surface of the semiconductor chip 100 may correspond to a lower surface of the chip base layer 110 of the semiconductor chip 100. The molding layer 200 may include an insulating molding material such as an epoxy molding compound (EMC).

At least one conductive post 250 may be provided on one side of the semiconductor chip 100. The conductive post 250 may vertically penetrate the molding layer 200. One end of the conductive post 250 may extend toward the upper surface of the conductive post 250 to be exposed at the upper surface of the molding layer 200. The other end of the conductive post 250 may extend toward the lower surface of the molding layer 200 to be exposed at the lower surface of the molding layer 200. The conductive post 250 may include a first post 260 and a second post 270.

Referring to FIGS. 1 and 2 together, the first post 260 may be provided. The first post 260 may have a tapered columnar shape. An upper surface and a lower surface of the first post 260 may have a circular shape. Alternatively, the upper surface and the lower surface of the first post 260 may have various shapes such as a tetragon or a hexagon. A first width W1 of the upper surface of the first post 260 may be greater than a second width W2 of the lower surface of the first post 260. The first width W1 may be about 1.5 times to about 7 times the second width W2. The first width W1 may be about 1 μm to about 50 μm, and the second width W2 may be about 1 μm to about 5 μm, but the inventive concept is not limited thereto, and the first width W1 and the second width W2 of the first post 260 may be variously provided as needed. The first post 260 may include a metal material such as copper (Cu) or tungsten (W).

The conductive post 250 may further include a seed layer 280. The seed layer 280 may be provided on the lower surface of the first post 260. The seed layer 280 may cover the lower surface of the first post 260. The seed layer 280 may extend from the lower surface of the first post 260 onto an outer circumferential surface of the first post 260. The seed layer 280 may cover the outer circumferential surface of the first post 260. The outer circumferential surface of the first post 260 may be spaced apart from the molding layer 200 by the seed layer 280. According to other embodiments, as illustrated in FIG. 3, the seed layer 280 may cover the lower surface of the first post 260, and may not cover the outer circumferential surface of the first post 260. The upper surface of the first post 260 may not be covered by the seed layer 280, and may be exposed. A lowermost end or lower surface of the seed layer 280 may be exposed at the lower surface of the molding layer 200. A thickness of the seed layer 280 may be about 1 nm to about 900 nm. The seed layer 280 may include a metal material. For example, the seed layer 280 may include gold (Au) or silver (Ag).

The second post 270 may be disposed on the first post 260. The second post 270 may have the same shape as or a similar shape to the first post 260. The second post 270 may have a tapered columnar shape. An upper surface and a lower surface of the second post 270 may have a circular shape (e.g., when viewed in plan view). Alternatively, the upper surface and the lower surface of the second post 270 may have various shapes such as a tetragon or a hexagon. A width of the upper surface of the second post 270 may be greater than a width of the lower surface of the second post 270. That is, a width of the second post 270 may become smaller toward the first post 260. The width of the upper surface of the second post 270 may be about 1.5 times to about 7 times the width of the lower surface of the second post 270. The width of the upper surface of the second post 270 may be about 10 μm to about 50 μm, and the width of the lower surface of the second post 270 may be about 1 μm to about 5 μm, but the inventive concept is not limited thereto, and the width of the upper surface and the width of the lower surface of the second post 270 may be variously provided as needed. The lower surface of the second post 270 may be in contact with the upper surface of the first post 260. Accordingly, the upper surface of the first post 260 may be partially in contact with the molding layer 200. The width of the lower surface of the second post 270 may be smaller than the first width W1 of the upper surface of the first post 260. That is, the width of the first post 260 may be greater than the width of the second post 270 on a contact surface of the first post 260 and the second post 270. An outer circumferential surface the second post 270 may be in contact with the molding layer 200. The upper surface of the second post 270 may be exposed at the upper surface of the molding layer 200. The second post 270 may include a metal material such as copper (Cu) or tungsten (W).

According to embodiments of the inventive concept, since the conductive post 250 is formed by stacking a plurality of first and second posts 260 and 270, the conductive post 250 having a great height may be provided. In addition, the conductive post 250 having a great aspect ratio, and not being one large post may be provided. This will be described later in more detail with a method for manufacturing a semiconductor package.

In addition, each of the first and second posts 260 and 270 may have a tapered shaped. In particular, since the width of the upper surface of the first post 260 in contact with the second post 270 is formed great, a structural defect in which the second post 270 is misaligned with the first post 260 during formation of the second post 270 may not occur. That is, structural stability may be improved, and the semiconductor package having no contact failure between the first and second posts 260 and 270 may be provided.

Referring to FIG. 1 continuously, a substrate 300 may be provided on the molding layer 200. The substrate 300 may cover the upper surface of the semiconductor chip 100, the upper surface of the molding layer 200, and an upper surface of the conductive post 250. The active surface of the semiconductor chip 100 may face the substrate 300. The substrate 300 may be a substrate for redistribution. For example, the substrate 300 may include one substrate wiring layer or at least two substrate wiring layers mutually stacked. Each of the substrate wiring layers may include a substrate insulating pattern 310 and a substrate wiring pattern 320 in the substrate insulating pattern 310. The substrate wiring pattern 320 of any one substrate wiring layer may be electrically connected to the substrate wiring pattern 320 of another substrate wiring layer adjacent thereto. Hereinafter, the substrate insulating pattern 310 and the substrate wiring pattern 320 will be described with reference to one substrate wiring layer.

The substrate insulating pattern 310 may include insulating polymer or photosensitive polymer (PID). For example, the photosensitive polymer may include at least one of photosensitive polyimide (PI), polybenzoxazole (PBO), phenol-based polymer or benzocyclobutene-based polymer. Alternatively, the substrate insulating pattern 310 may include an insulating material. For example, the substrate insulating pattern 310 may include silicon oxide (SiO), silicon nitride (SiN), silicon oxynitride (SiON) or insulating polymer.

The substrate wiring pattern 320 may be provided on the substrate insulating pattern 310. The substrate wiring pattern 320 may horizontally extend on the substrate insulating pattern 310. The substrate wiring pattern 320 may be provided on an upper surface of the substrate insulating pattern 310. The substrate wiring pattern 320 may protrude onto the upper surface of the substrate insulating pattern 310. The substrate wiring pattern 320 may be covered on the substrate insulating pattern 310 by another substrate insulating pattern 310 disposed on the substrate wiring pattern 320. Portions of the substrate wiring pattern 320 provided on an uppermost substrate wiring layer may be substrate pads provided by first external terminals 302. Alternatively, the portions of the substrate wiring pattern 320 provided on the uppermost substrate wiring layer may be substrate pads connected by an external device, a package or chips. Like the above, the substrate wiring pattern 320 may be a pad portion or wire portion of the substrate wiring layer. That is, the substrate wiring pattern 320 may be a configuration for horizontal redistribution in the substrate 300. The substrate wiring pattern 320 may include a conductive material. For example, the substrate wiring pattern 320 may include metal such as copper (Cu).

The substrate wiring pattern 320 may have a damascene structure. For example, the substrate wiring pattern 320 may have a via protruding onto a lower surface thereof. The via may be a configuration for vertically connecting the substrate wiring patterns 320 of the substrate wiring layers adjacent to each other. For example, the via may penetrate the substrate insulating pattern 310 from the lower surface of the substrate wiring pattern 320 to be connected to an upper surface of the substrate wiring pattern 320 of another substrate wiring layer located thereunder. Alternatively, the via may be a configuration for connecting the substrate wiring pattern 320 of a lowermost substrate wiring layer and the semiconductor chip 100 or the conductive post 250. For example, the via may penetrate a lowermost substrate insulating pattern 310 from the upper surface of the substrate wiring pattern 320 to be connected to upper surfaces of the chip pads 125 of the semiconductor chip 100 or the upper surface of the second post 270 of the conductive post 250. That is, upper portions of the substrate wiring pattern 320 located on the upper surface of the substrate insulating pattern 310 may be a head portion used as a horizontal wire or pad, and the via of the substrate wiring pattern 320 may be a tail portion. The substrate wiring pattern 320 may have a T shape.

The first external terminals 302 may be provided on upper surfaces of the substrate pads exposed at an upper surface of the substrate 300. The first external terminals 302 may include a solder ball or solder bump, and the semiconductor package may be provided in a form of ball grid array (BGA), fine ball grid array (FBGA) or land grid array (LGA) depending on a type and a disposition of the first external terminals 302.

A protective layer 410 may be provided under the molding layer 200. The protective layer 410 may cover the lower surface of the semiconductor chip 100, the lower surface of the molding layer 200 and the lower surface of the conductive post 250. In this case, the protective layer 410 may have an opening exposing a lower surface of the conductive post 250. The protective layer 410 may include insulating polymer or photosensitive polymer (PID). In some embodiments, the protective layer 410 may not be needed and, as such, will not be provided.

Second external terminals 420 may be provided under the protective layer 410. The second external terminals 420 may be connected to the lower surface of the seed layer 280 of the conductive post 250 exposed at the protective layer 410. The second external terminals 420 may include a solder ball or solder bump, and the semiconductor package may be provided in a form of ball grid array (BGA), fine ball grid array (FBGA) and land grid array (LGA) depending on a type and a disposition of the second external terminals 420.

In embodiments described below, the components described in embodiment of FIGS. 1 to 3 use the same reference numerals or symbols, and for convenience of description, description therefor will be omitted or briefly made. That is, differences of the embodiments below from the embodiments of FIGS. 1 to 3 will be mainly described.

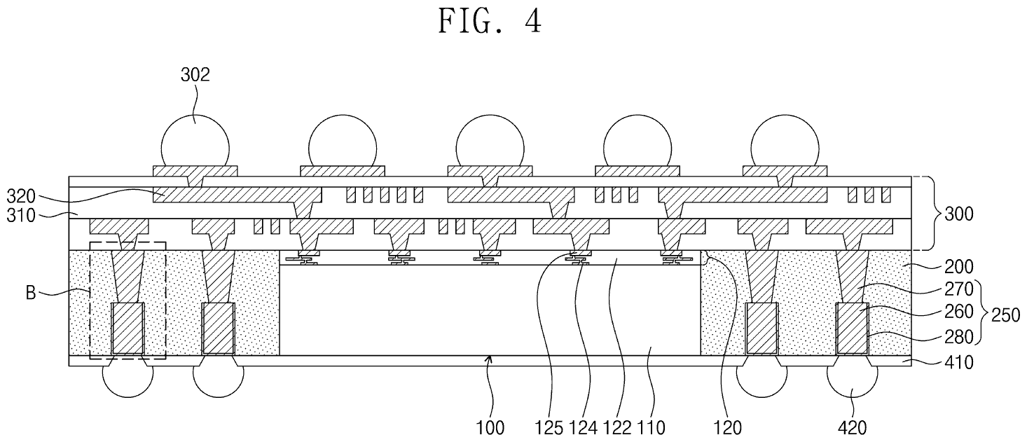

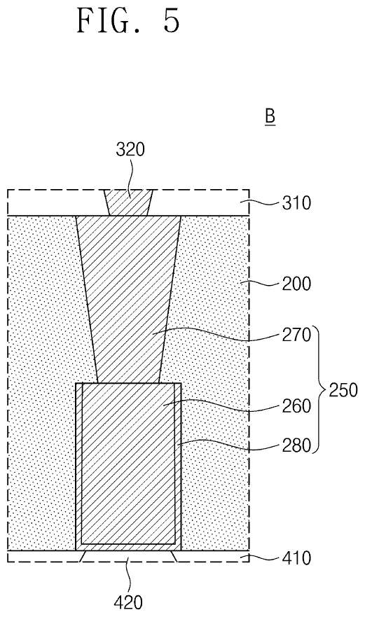

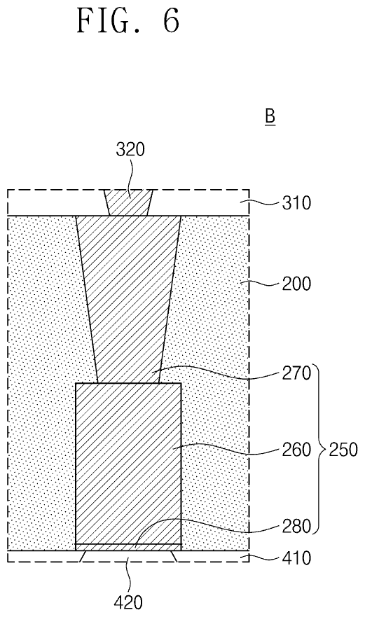

FIG. 4 is a cross-sectional view for describing a semiconductor package according to embodiments of the inventive concept. FIGS. 5 and 6 are enlarged diagrams illustrating region B of FIG. 4.

Referring to FIGS. 4 and 5, the first post 260 may be provided. The first post 260 may have a shape of a column having a constant width. The upper surface and the lower surface of the first post 260 may have a circular shape (i.e., the first post 260 is cylindrical). Alternatively, the upper surface and the lower surface of the first post 260 may have various shapes such as a tetragon or a hexagon. The width of the upper surface of the first post 260 may be substantially the same as the width of the lower surface of the first post 260. The width of the first post 260 may be about 10 μm to about 50 μm, but the inventive concept is not limited thereto, and the width of the first post 260 may be variously provided as needed.

The seed layer 280 may be provided on the lower surface of the first post 260. The seed layer 280 may cover the lower surface of the first post 260. The seed layer 280 may extend from the lower surface of the first post 260 onto the outer circumferential surface of the first post 260. The seed layer 280 may cover the circumferential surface of the first post 260. The outer circumferential surface of the first post 260 may be spaced apart from the molding layer 200 by the seed layer 280. According to other embodiments, as illustrated in FIG. 6, the seed layer 280 may cover the lower surface of the first post 260, and may not cover the outer circumferential surface of the first post 260. The upper surface of the first post 260 may not be covered by the seed layer 280 and may be exposed.

The second post 270 may be disposed on the first post 260. The second post 270 may have a shape different from the first post 260. The second post 270 may have a tapered columnar shape. The upper surface and the lower surface of the second post 270 may have a circular shape. Alternatively, the upper surface and the lower surface of the second post 270 may have various shapes such as a tetragon or a hexagon. A width of the upper surface of the second post 270 may be greater than a width of the lower surface of the second post 270. The lower surface of the second post 270 may be in contact with the upper surface of the first post 260. The width of the lower surface of the second post 270 may be smaller than the width of the first post 260 or the width of the upper surface of the first post 260. The outer circumferential surface of the second post 270 may be in contact with the molding layer 200.

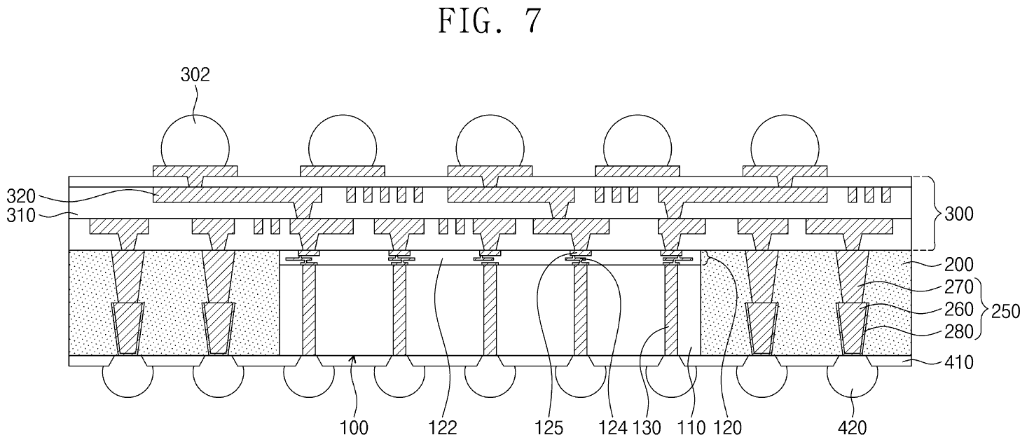

FIG. 7 is a cross-sectional view for describing a semiconductor package according to embodiments of the inventive concept.

Referring to FIG. 7, the semiconductor chip 100 may further include at least one chip via 130. The chip via 130 may be patterns for vertical wiring. The chip via 130 may vertically penetrate the chip base layer 110 to be connected to the chip circuit layer 120. For example, the chip via 130 may be connected to the chip circuit pattern 124 of the chip circuit layer 120, or may be connected to an integrated element or integrated circuits formed in the chip base layer 110. The chip via 130 may vertically penetrate the chip base layer 110 to be exposed at the lower surface of the chip base layer 110. For example, the chip via 130 may include tungsten (W).

The protective layer 410 may be provided under the molding layer 200. The protective layer 410 may cover the lower surface of the semiconductor chip 100, the lower surface of the molding layer 200, and the lower surface of the conductive post 250. In this case, the protective layer 410 may have openings exposing the lower surface of the conductive post 250 and a lower surface of the chip via 130.

The second external terminals 420 may be provided under the protective layer 410. The second external terminals 420 may be connected to the lower surface of the conductive post 250 and the lower surface of the chip via 130 exposed by the protective layer 410.

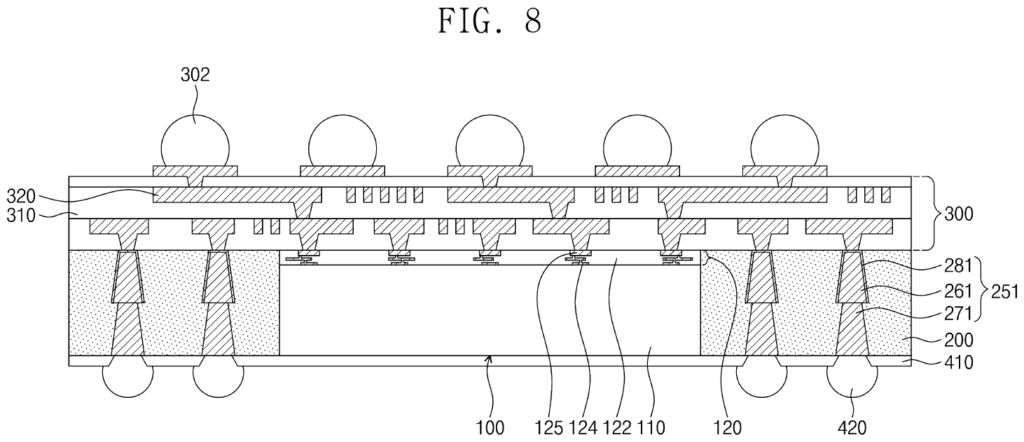

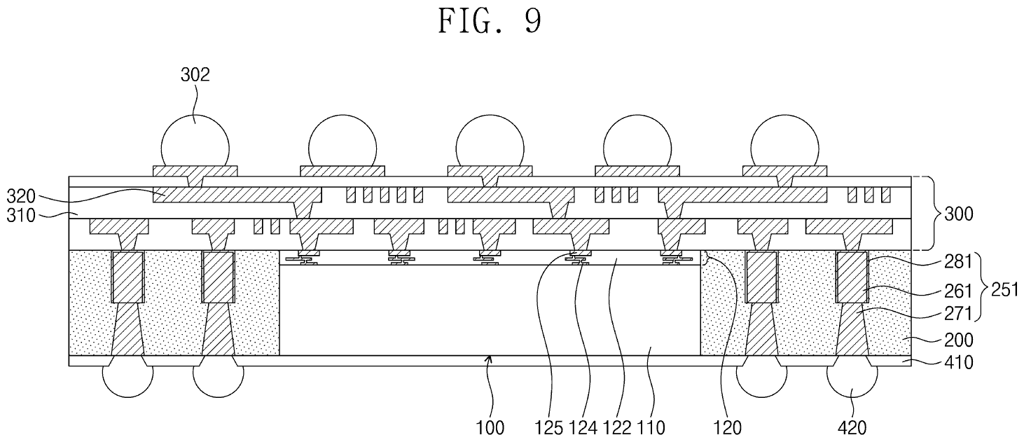

FIGS. 8 and 9 are cross-sectional views for describing a semiconductor package according to embodiments of the inventive concept.

Referring to FIG. 9, unlike embodiments of FIGS. 1 to 7, a conductive post 251 may have a structure in which a first post 261 is disposed on a second post 271.

The first post 261 may be provided. The first post 261 may have a tapered columnar shape. A width of an upper surface of the first post 261 may be smaller than a width of a lower surface of the first post 261. The width of the lower surface of the first post 261 may be about 1.5 times to about 7 times the width of the upper surface of the first post 261.

A seed layer 281 may be provided on the upper surface of the first post 261. The seed layer 281 may cover the upper surface of the first post 261. The seed layer 281 may extend from the upper surface of the first post 261 onto an outer circumferential surface of the first post 261. The seed layer 281 may cover the outer circumferential surface of the first post 261. According to other embodiments, the seed layer 281 may cover the upper surface of the first post 261, and may not cover the outer circumferential surface of the first post 261. The lower surface of the first post 261 may not be covered by the seed layer 281, and may be exposed. An uppermost end or upper surface of the seed layer 281 may be exposed at the upper surface of the molding layer 200.

The second post 271 may be disposed under the first post 261. The second post 271 may have the same shape as or a similar shape to the first post 261. A width of an upper surface of the second post 271 may be smaller than a width of a lower surface of the second post 271. That is, a width of the second post 271 may become smaller toward the first post 261. The width of the lower surface of the second post 271 may be about 1.5 times to about 7 times the width of the upper surface of the second post 271. The upper surface of the second post 271 may be in contact with the lower surface of the first post 261. The width of the upper surface of the second post 271 may be smaller than the width of the lower surface of the first post 261. That is, the width of the first post 261 may be greater than the width of the second post 271 on a contact surface of the first post 261 and the second post 271. An outer circumferential surface of the second post 271 may be in contact with the molding layer 200. The upper surface of the second post 271 may be exposed at the lower surface of the molding layer 200.

The substrate 300 may be provided on the molding layer 200. For example, the via may penetrate a lowermost substrate insulating pattern 310 from the upper surface of the substrate wiring pattern 320 to be connected to the upper surfaces of the chip pads 125 of the semiconductor chip 100 or an upper surface of the seed layer 281 of the conductive post 251.

The second external terminals 420 may be provided under the protective layer 410. The second external terminals 420 may be connected to the lower surface of the second post 271 of the conductive post 251 exposed at the protective layer 410.

According to other embodiments, as illustrated in FIG. 9, the first post 261 may be provided. The first post 261 may have a shape of a column having a constant width. The width of the upper surface of the first post 261 may be substantially the same as the width of the lower surface of the first post 261.

The seed layer 281 may be provided on the upper surface of the first post 261. The seed layer 281 may cover the upper surface of the first post 261. The seed layer 281 may extend from the upper surface of the first post 261 onto the outer circumferential surface of the first post 261. According to other embodiments, the seed layer 281 may cover the upper surface of the first post 261, and may not cover the outer circumferential surface of the first post 261.

The second post 271 may be disposed under the first post 261. The second post 271 may have a shape different from the first post 261. The second post 271 may have a tapered columnar shape. The width of the upper surface of the second post 271 may be smaller than the width of the lower surface of the second post 271. The upper surface of the second post 271 may be in contact with the lower surface of the first post 261. The width of the upper surface of the second post 271 may be smaller than a width of the first post 261 or the width of the lower surface of the first post 261.

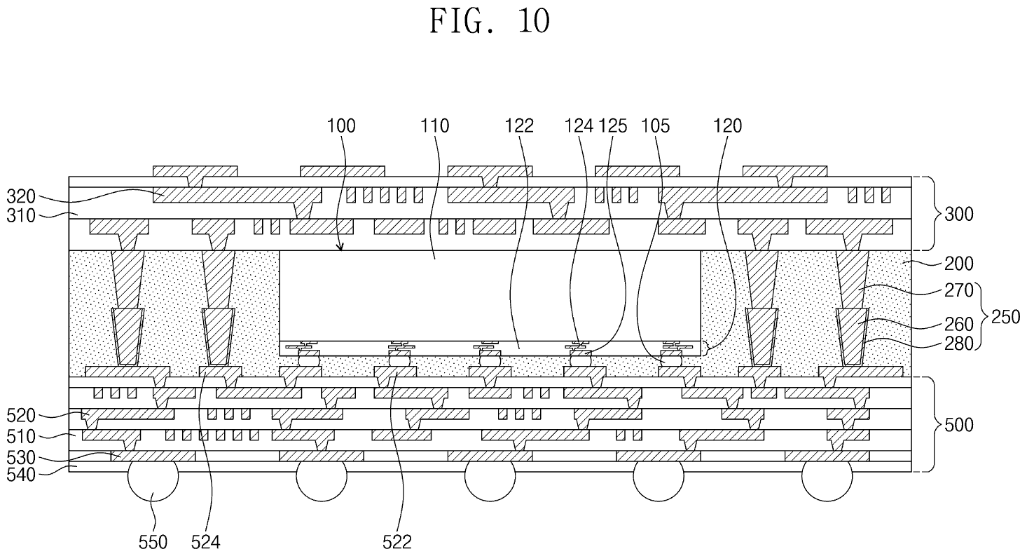

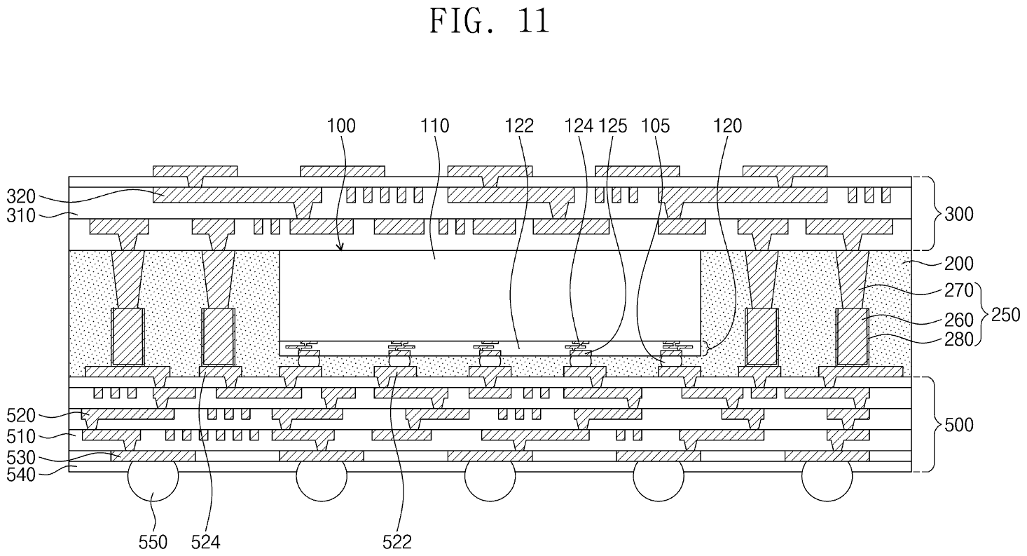

FIGS. 10 and 11 are cross-sectional views for describing a semiconductor package according to embodiments of the inventive concept.

Referring to FIG. 10, a first substrate 500 may be provided. The first substrate 500 may be a redistribution substrate. For example, the first substrate 500 may include one first substrate wiring layer or at least two first substrate wiring layers mutually stacked. Each of the first substrate wiring layers may include a first substrate insulating pattern 510 and a first substrate wiring pattern 520 in the first substrate insulating pattern 510. The first substrate wiring pattern 520 of any one first substrate wiring layer may be electrically connected to the first substrate wiring pattern 520 of another first substrate wiring layer adjacent thereto.

The first substrate insulating pattern 510 may include insulating polymer or photosensitive polymer (PID). For example, the photosensitive polymer may include at least one of photosensitive polyimide (PI), polybenzoxazole (PBO), phenol-based polymer or benzocyclobutene-based polymer. Alternatively, the first substrate insulating pattern 510 may include an insulating material. For example, the first substrate insulating pattern 510 may include silicon oxide (SiO), silicon nitride (SiN), silicon oxynitride (SiON) or insulating polymer.

The first substrate wiring pattern 520 may be provided on the first substrate insulating pattern 510. The first substrate wiring pattern 520 may horizontally extend on the first substrate insulating pattern 510. The first substrate wiring pattern 520 may be provided on an upper surface of the first substrate insulating pattern 510. The first substrate wiring pattern 520 may protrude onto the upper surface of the first substrate insulating pattern 510. The first substrate wiring pattern 520 may be covered on the first substrate insulating pattern 510 by another first substrate insulating pattern 510 disposed thereon. The first substrate wiring pattern 520 provided in an uppermost first substrate wiring layer may serve as a substrate pad to which the semiconductor chip 100 and the conductive post 250 are connected. For example, portions of the first substrate wiring pattern 520 provided in the uppermost first substrate wiring layer may be first substrate pads 522 on which the semiconductor chip 100 is mounted, and other portions of the first substrate wiring pattern 520 provided in the uppermost first substrate wiring layer may be second substrate pads 524 to which the conductive post 250 is connected. Like the above, the first substrate wiring pattern 520 may be a pad portion or wire portion of the first substrate wiring layer. That is, the first substrate wiring pattern 520 may be a configuration for horizontal redistribution in the first substrate 500. The first substrate wiring pattern 520 may include a conductive material. For example, the first substrate wiring pattern 520 may include metal such as copper (Cu).

The first substrate wiring pattern 520 may have a damascene structure. For example, the first substrate wiring pattern 520 may have a via protruding onto a lower surface thereof. The via may be a configuration for vertically connecting the first substrate wiring patterns 520 of wiring layers adjacent to each other. Alternatively, the via may be a configuration for connecting the first substrate wiring pattern 520 and the external pads 530 of a lowermost wiring layer. For example, the via may penetrate the first substrate insulating pattern 510 from the lower surface of the first substrate wiring pattern 520 to be connected to an upper surface of the first substrate wiring pattern 520 of another wiring layer located thereunder. Alternatively, the via may penetrate a lowermost first substrate insulating pattern 510 from the lower surface of the first substrate wiring pattern 520 to be connected to upper surfaces of external pads 530. That is, upper portions of the first substrate wiring pattern 520 located on the first substrate insulating pattern 510 may be a head portion used as a horizontal wire or pad, and the via of the first substrate wiring pattern 520 may be a tail portion. The first substrate wiring pattern 520 may have a T shape.

The external pads 530 may be provided on a lower surface of a lowermost first substrate wiring layer. The external pads 530 may be electrically connected to the first substrate wiring pattern 520. The external pads 530 may serve as a pad to which the external terminals 550 are connected.

A substrate protective layer 540 may be provided. The substrate protective layer 540 may cover a lower surface of the first substrate wiring layer, and may expose the external pads 530. The external terminals 550 may be provided on lower surfaces of the exposed external pads 530. The external terminals 550 may include a solder ball or solder bump, and the semiconductor package may be provided in a form of ball grid array (BGA), fine ball grid array (FBGA), or land grid array (LGA) depending a type and a disposition of the external terminals 550.

According to other embodiments, the first substrate 500 may be a printed circuit board (PCB). For example, the first substrate 500 may have a core layer and peripheral portions for connecting wires on and under the core layer.

The semiconductor chip 100 may be provided on the first substrate 500. The semiconductor chip 100 may be substantially the same as or similar to the semiconductor chip 100 described with reference to FIGS. 1 to 10. For example, the semiconductor chip 100 may have the chip base layer 110 on which integrated elements are formed, and the chip circuit layer 120 covering the chip base layer 110. The chip circuit layer 120 may have the chip circuit insulating pattern 122, the chip circuit pattern 124 and the chip pads 125. The semiconductor chip 100 may be disposed on the first substrate 500 in a face-down form. That is, the chip pads 125 of the semiconductor chip 100 may face the first substrate 500.

Chip connection terminals 105 may be provided on the lower surface of the semiconductor chip 100. The chip connection terminals 105 may be connected to the chip pads 125 of the semiconductor chip 100. For example, the chip connection terminals 105 may include a solder ball, or the like.

The semiconductor chip 100 may be mounted on the first substrate 500. For example, the semiconductor chip 100 may be electrically connected to the first substrate 500 through the chip connection terminals 105. The chip connection terminals 105 may be provided between the first substrate pads 522 of the first substrate 500 and the chip pads 125 of the semiconductor chip 100.

The molding layer 200 may be provided on the first substrate 500. The molding layer 200 may cover the semiconductor chip 100 on the first substrate 500.

At least one conductive post 250 may be provided on one side of the semiconductor chip 100. The conductive post 250 may vertically penetrate the molding layer 200 to be connected to the second substrate pads 524 of the first substrate 500. The upper surface of the conductive post 250 may be exposed at the upper surface of the molding layer 200. The conductive post 250 may be substantially the same as or similar to the conductive post 250/251 described with reference to FIGS. 1 to 10. For example, the conductive post 250 may include the first post 260, the second post 270 and the seed layer 280. The first post 260 may have a tapered shape in which the width thereof becomes smaller toward the first substrate 500. The second post 270 may have a tapered shape in which the width thereof becomes smaller toward the first substrate 500. The second post 270 may be in contact with the upper surface of the first post 260. The seed layer 280 may cover the lower surface, or the lower surface and the outer circumferential surface of the first post 260.

According to other embodiments, as illustrated in FIG. 11, the first post 260 may be provided. The first post 260 may have a shape of a column having a constant width. The width of the upper surface of the first post 260 may be substantially the same as the width of the lower surface of the first post 260.

A second substrate 300 may be provided on the molding layer 200. The second substrate 300 may be substantially the same as or similar to the substrate 300 described with reference to FIGS. 1 to 10. For example, the second substrate 300 may include one second substrate wiring layer or at least two second substrate wiring layers mutually stacked. Each of the second substrate wiring layers may include the substrate insulating pattern 310 and the substrate wiring pattern 320 in the substrate insulating pattern 310.

FIG. 12 is a cross-sectional view for describing a semiconductor package according to embodiments of the inventive concept.

Referring to FIG. 12, the molding layer 200 may include a first molding layer 210 and a second molding layer 220.

The first molding layer 210 may surround the first post 260, and lower portions of the seed layer 280 and the semiconductor chip 100. An upper surface of the first molding layer 210 may be located at a lower level than the upper surface of the semiconductor chip 100. The upper surface of the first molding layer 210 may be coplanar with the upper surface of the first post 260. That is, the first post 260 may vertically penetrate the first molding layer 210.

The second molding layer 220 may be disposed on the first molding layer 210. The second molding layer 220 may be in contact with the upper surface of the first molding layer 210. The second molding layer 220 may surround upper portions of the second post 270 and the semiconductor chip 100. An upper surface of the second molding layer 220 may be located at the same level as the upper surface of the semiconductor chip 100. The upper surface of the second molding layer 220 may be coplanar with the upper surface of the second post 270. That is, the second post 270 may vertically penetrate the second molding layer 220.

An interface between the first molding layer 210 and the second molding layer 220 may be coplanar with an interface between the first post 260 and the second post 270. The first molding layer 210 and the second molding layer 220 may be composed of the same material, or different materials.

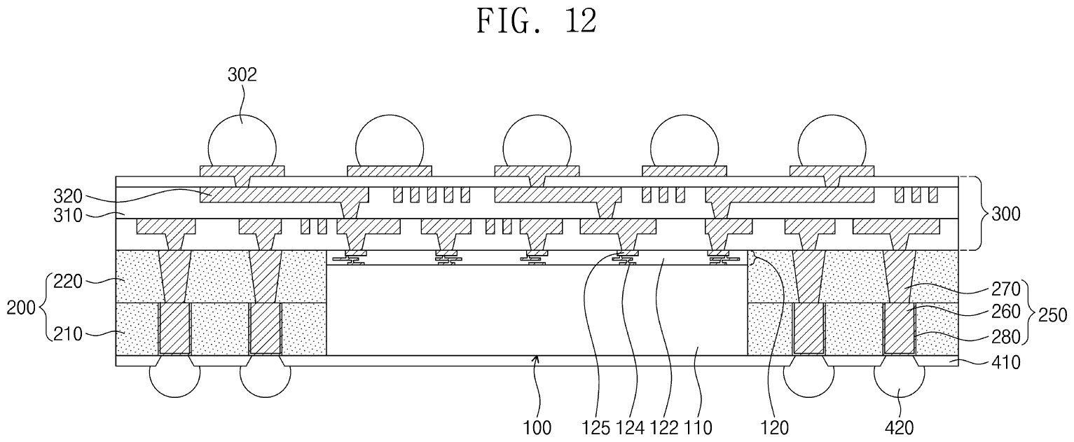

FIG. 13 is a cross-sectional view for describing a semiconductor package according to embodiments of the inventive concept.

Referring to FIG. 13, the first substrate 500 may be provided. The first substrate 500 may be substantially the same as or similar to the first substrate 500 described with reference to FIGS. 10 to 11. For example, the first substrate 500 may include one first substrate wiring layer or at least two first substrate wiring layers mutually stacked. Each of the first substrate wiring layers may include the first substrate insulating pattern 510 and the first substrate wiring pattern 520 in the first substrate insulating pattern 510. Portions of the first substrate wiring pattern 520 provided in an uppermost first substrate wiring layer may be the first substrate pads 522, and other portions of the first substrate wiring pattern 520 provided in the uppermost first substrate wiring layer may be the second substrate pads 524. Upper surfaces of the first substrate pads 522 and upper surfaces of the second substrate pads 524 may be coplanar with the upper surface of the first substrate insulating pattern 510 of the uppermost first substrate wiring layer.

A chip stack may be disposed on the first substrate 500. The chip stack may include semiconductor chips 101, 102 and 103 sequentially stacked. Each of the semiconductor chips 101, 102 and 103 may be substantially the same as to similar to the semiconductor chip 100 described with reference to FIGS. 1 to 10. For example, the semiconductor chip 100 may vertically penetrate the chip base layer 110 on which integrated elements are formed, the chip circuit layer 120 covering the chip base layer 110, and the chip via 130 vertically penetrating the chip base layer 110 to be connected to the chip circuit layer 120. The chip circuit layer 120 may have the chip circuit insulating pattern 122, the chip circuit pattern 124 and the chip pads 125. The semiconductor chips 101, 102 and 103 may be disposed on the first substrate 500 in a face-down form. That is, the chip pads 125 of the semiconductor chips 101, 102 and 103 may face the first substrate 500. Hereinafter, for convenience of description, the semiconductor chips 101, 102 and 103 may be respectively referred to as a first chip 101, a second chip 102 and a third chip 103 along a sequence in which the semiconductor chips 101, 102 and 103 are stacked on the first substrate 500.

The first chip 101 may be mounted on the first substrate 500. For example, the chip circuit layer 120 of the first chip 101 may face an upper surface of the first substrate 500. The chip circuit layer 120 of the first chip 101 may be in contact with the upper surface of the first substrate 500. The chip pads 125 of the first chip 101 may be in contact with the first substrate pads 522 of the first substrate 500 on an interface between the first chip 101 and the first substrate 500. The first chip 101 may be directly bonded to the first substrate 500. For example, the chip pads 125 of the first chip 101 and the first substrate pads 522 of the first substrate 500 may form an be intermetallic hybrid bonding on an interface between the first chip 101 and the first substrate 500. In the present specification, the hybrid bonding means a bonding in which two components including the same type material fuse at an interface thereof, or a bonding in which a first component including a first material and a second component including a second material which is a compound of the first material fuse at an interface thereof. For example, the chip pads 125 and the first substrate pads 522 may have a continuous configuration, and interfaces between the chip pads 125 and the first substrate pads 522 may not be visually seen.

The second chip 102 may be mounted on the first chip 101. For example, the chip circuit layer 120 of the second chip 102 may face an upper surface of the first chip 101. The chip circuit layer 120 of the second chip 102 may be in contact with the upper surface of the first chip 101. The chip pads 125 of the second chip 102 may be in contact with the chip vias 130 of the first chip 101 on an interface between the second chip 102 and the first chip 101. The second chip 102 may be directly bonded to the first chip 101. For example, the chip pads 125 of the second chip 102 and the chip vias 130 of the first chip 101 may form an intermetallic hybrid bonding on the interface between the second chip 102 and the first chip 101. For example, the chip pads 125 and the chip vias 130 may have a continuous configuration, and interfaces between the chip pads 125 and the chip via 130 may not be visually seen.

The third chip 103 may be mounted on the second chip 102. A manner in which the third chip 103 is mounted on the second chip 102 may be substantially the same as or similar to a manner in which the second chip 102 is mounted on the first chip 101. For example, the chip pads 125 of the third chip 103 may be in contact with the chip vias 130 of the second chip 102 on an interface between the third chip 103 and the second chip 102. The third chip 103 may be directly bonded to the second chip 102. For example, the chip pads 125 of the third chip 103 and the chip vias 130 of the second chip 102 may form an intermetallic hybrid bonding on the interface between the third chip 103 and the second chip 102. For example, the chip pads 125 and the chip vias 130 may have a continuous configuration, and interfaces between the chip pads 125 and the chip vias 130 may not be visually seen.

Molding layers 201, 202 and 203 may be disposed on the first substrate 500. A third molding layer 201 surrounding the first chip 101 may be disposed on the first substrate 500. An upper surface of the third molding layer 201 may be coplanar with the upper surface of the first chip 101. A fourth molding layer 202 surrounding the second chip 102 may be disposed on the third molding layer 201. An upper surface of the fourth molding layer 202 may be coplanar with an upper surface of the second chip 102. A fifth molding layer 203 may be disposed on the fourth molding layer 202. An upper surface of the fifth molding layer 203 may be coplanar with an upper surface of the third chip 103.

At least one conductive post 252 may be provided on one side of the chip stack. The conductive post 252 may vertically penetrate the molding layers 201, 202 and 203. The conductive post 252 may be in contact with the second substrate pads 524 of the first substrate 500. The conductive post 252 may include a first post 262 and a plurality of second posts 272. The first post 262 and the second posts 272 of the conductive post 252 may correspond to the first post 260 and the second post 270 described with reference to FIGS. 1 to 10.

The first post 262 may vertically penetrate the third molding layer 201. The upper surface of the third molding layer 201 may be coplanar with an upper surface of the first post 262. The first post 262 may have a shape of a column having a constant width, or a tapered shape in which a width thereof becomes smaller toward the first substrate 500.

The seed layer 282 may cover a lower surface of the first post 262. The seed layer 282 may extend from the lower surface of the first post 262 onto an outer circumferential surface of the first post 262. A lowermost end or lower surface of the seed layer 282 may be exposed at a lower surface of the third molding layer 201.

One of the second posts 272 may vertically penetrate the fourth molding layer 202. The upper surface of the fourth molding layer 202 may be coplanar with an upper surface of the one second post 272. The one second post 272 may be in contact with the upper surface of the first post 262. An interface between the one second post 272 and the first post 262 may be coplanar with the interface between the first chip 101 and the second chip 102. An outer circumferential surface of the one second posts 272 may be in contact with the fourth molding layer 202.

Another one of the second posts 272 may vertically penetrate the fifth molding layer 203. The upper surface of the fifth molding layer 203 may be coplanar with the upper surface of the other one second post 272. The other one second post 272 may be in contact with the upper surface of the second post 272 located thereunder. An interface the second posts in contact with each other may be coplanar with the interface between the second chip 102 and the third chip 103. The outer circumferential surface of the other one second post 272 may be in contact with the fifth molding layer 203.

The second posts 272 may have a tapered shape in which a width thereof becomes smaller toward the first substrate 500.

The second substrate 300 may be provided on the fifth molding layer 203. The second substrate 300 may be substantially the same as or similar to the second substrate 300 described with reference to FIGS. 1 to 10. For example, the second substrate 300 may include one second substrate wiring layer or at least two second substrate wiring layers mutually stacked. Each of the second substrate wiring layers may include the substrate insulating pattern 310 and the substrate wiring pattern 320 in the substrate insulating pattern 310.

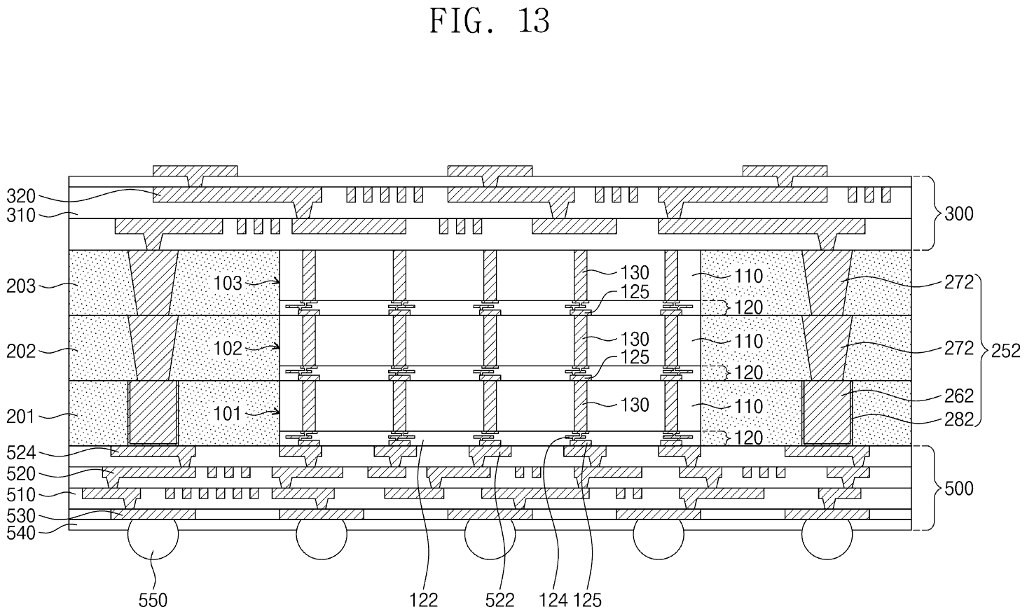

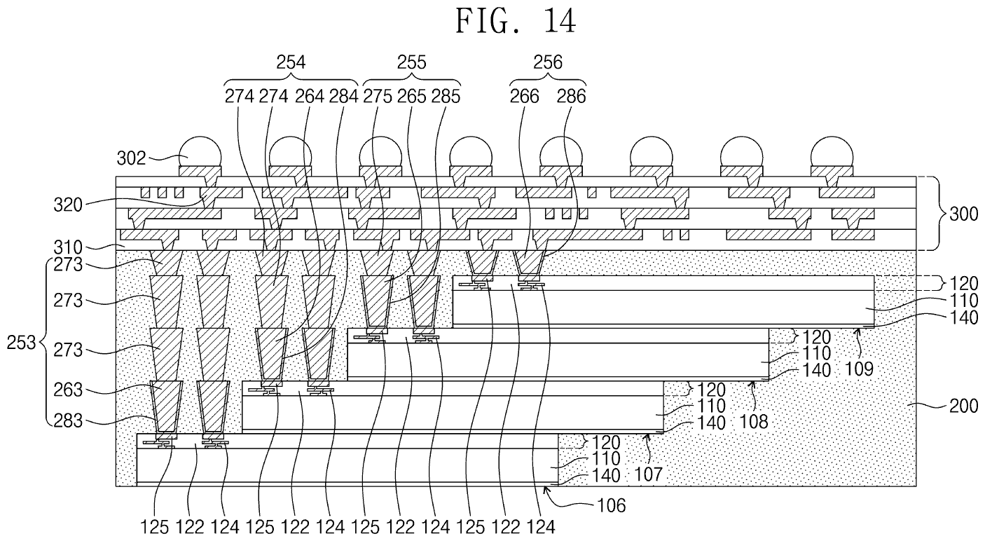

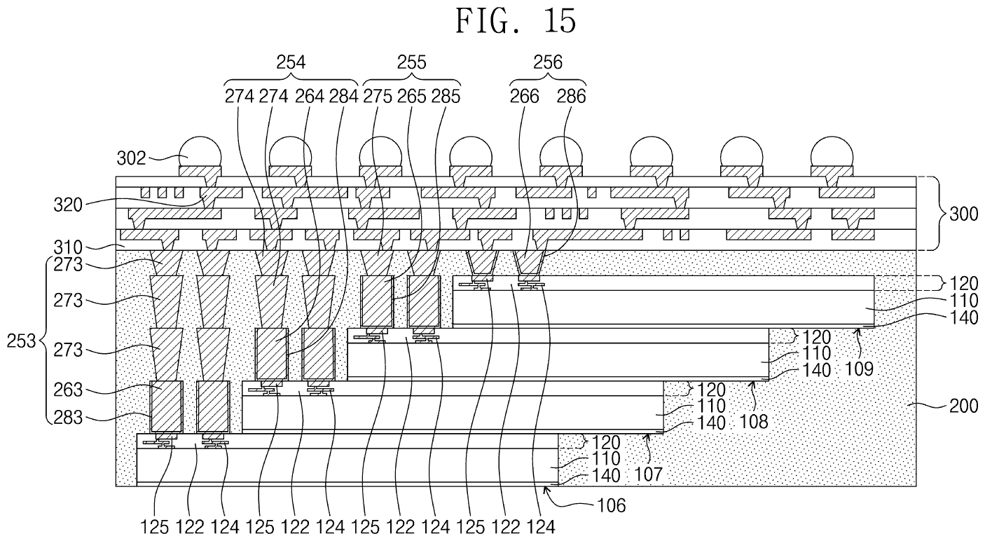

FIGS. 14 and 15 are cross-sectional views for describing a semiconductor package according to embodiments of the inventive concept.

Referring to FIG. 14, the semiconductor package may include the chip stack.

The chip stack may have a plurality of semiconductor chips 106, 107, 108 and 109 mutually stacked in a vertical direction. The semiconductor chips 106, 107, 108 and 109 may include the same semiconductor chip as each other, or may respectively include semiconductor chips different from each other. For example, the semiconductor chips 106, 107, 108 and 109 may be memory chips. Alternatively, a lowermost semiconductor chip 106 may be a logic chip, and the remaining semiconductor chips 107, 108 and 109 may be memory chips. FIG. 14 illustrates the chip stack having four semiconductor chips 106, 107, 108 and 109, but the inventive concept is not limited thereto.

The semiconductor chips 106, 107, 108 and 109 may be substantially the same as or similar to the semiconductor chip 100 described with reference to FIGS. 1 to 10. For example, the semiconductor chips 106, 107, 108 and 109 may each have the chip base layer 110 on which integrated elements are formed, and the chip circuit layer 120 covering the chip base layer 110. The chip circuit layer 120 may have the chip circuit insulating pattern 122, the chip circuit pattern 124 and the chip pads 125. The semiconductor chips 106, 107, 108 and 109 may be disposed in a face-up form. Hereinafter, for convenience of description, the semiconductor chips 106, 107, 108 and 109 may be referred to as a fourth chip 106, a fifth chip 107, a sixth chip 108 and a seventh chip 109 along a stacking sequence.

The fourth to seventh chips 106, 107, 108 and 109 may be disposed having an offset stack structure, as illustrated in FIG. 14. For example, the fourth to seventh chips 106, 107, 108 and 109 may be stacked inclined in one direction parallel to an upper surface of the lowermost fourth chip 106, and may be stacked in an ascending sloped step shape (that is, a cascade shape or a staircase shape). More specifically, each of the fifth to seventh semiconductor chips 107, 108 and 109 may protrude from the fourth to sixth chips 106, 107 and 108 located thereunder in the one direction (i.e., the fifth chip 107 extends further in one direction than the underlying fourth chip 106, the sixth chip 108 extends further in one direction than the underlying fifth chip 107, etc., as illustrated).

Since the fourth to seventh chips 106, 107, 108 and 109 are stacked in the step shape, an upper surface (hereinafter, the upper surface will be referred to as an exposed surface) of each of the fourth to seventh chips 106, 107, 108 and 109 may be partially exposed. The exposed surfaces of the fourth to seventh chips 106, 107, 108 and 109 may be located adjacent to side surfaces of the fifth to seventh semiconductor chips 107, 108 and 109 located thereunder along an offset stack direction of the fourth to seventh chips 106, 107, 108 and 109. Here, the offset stack direction is defined as a direction in which when semiconductor chips are stacked, a semiconductor chip is shifted from another semiconductor chip located thereunder. The upper surfaces of the fourth to seventh chips 106, 107, 108 and 109 may be active surfaces. The chip pads 125 of the fourth to seventh chips 106, 107, 108 and 109 may be provided on the exposed surface on the upper surfaces of the fourth to seventh chips 106, 107, 108 and 109. Described differently, the chip pads 125 of the fourth to sixth chips 106, 107 and 108 may be located horizontally spaced apart from the fifth to seventh semiconductor chips 107, 108 and 109 located thereon.

Adhesive layers 140 may be respectively provided on lower surfaces of the fourth to seventh chips 106, 107, 108 and 109. The fifth to seventh semiconductor chips 107, 108 and 109 may be adhered to the fourth to sixth chips 106, 107 and 108 located thereunder using the adhesive layers 140. The adhesive layers 140 may include a die attach film (DAF).

The molding layer 200 may be provided. The molding layer 200 may surround the chip stack on a plan view. The molding layer 200 may surround the fourth to seventh chips 106, 107, 108 and 109. The molding layer 200 may cover the chip stack. The upper surface of the molding layer 200 may be located higher than an upper surface of the uppermost seventh chip 109.

Conductive posts 253, 254, 255 and 256 may be provided on the chip stack. The conductive posts 253, 254, 255 and 256 may vertically penetrate (i.e., extend through) the molding layer 200. One end of each of the conductive posts 253, 254, 255 and 256 may extend toward the upper surface of the molding layer 200. Upper surfaces of the conductive posts 253, 254, 255 and 256 may be exposed at the upper surface of the molding layer 200. The conductive posts 253, 254, 255 and 256 may include a first conductive post 253 connected to the fourth chip 106, a second conductive post 254 connected to the fifth chip 107, a third conductive post 255 connected to the sixth chip 108 and a fourth conductive post 256 connected to the seventh chip 109.

The first conductive post 253 may penetrate the molding layer 200 to be connected to the chip pad 125 of the fourth chip 106. The first conductive post 253 may include a third post 263 and a plurality of fourth posts 273. The third post 263 and the fourth post 273 may respectively correspond to the first post 260 and the second post 270 described with reference to FIGS. 1 to 10. A number of the fourth posts 273 may be the same as a number of the chips 107, 108 and 109 stacked on the fourth chip 106. An upper surface of the third post 263 may be located at the same level as an upper surface of the fifth chip 107, but the inventive concept is not limited thereto, and the upper surface of the third post 263 may be located at a different level from the upper surface of the fifth chip 107. The third post 263 may have a tapered shape in which a width thereof becomes smaller in a downward direction. According to other embodiments, as illustrated in FIG. 15, the third post 263 may have a shape of a column having a constant width. The seed layer 283 may cover a lower surface and an outer circumferential surface of the third post 263. The fourth posts 273 may be stacked on the third post 263. The fourth posts 273 may be in contact with the upper surface of the third post 263, or an upper surface of another fourth post 273 located thereunder. An upper surface of an uppermost fourth post 273 may be exposed at the upper surface of the molding layer 200. Each of the fourth posts 273 may have a tapered shape in which a width thereof becomes smaller toward the third post 263.

The second conductive post 254 may penetrate the molding layer 200 to be connected to the chip pad 125 of the fifth chip 107. The second conductive post 254 may include a fifth post 264 and a plurality of sixth posts 274. The fifth post 264 and the sixth post 274 may respectively correspond to the first post 260 and the second post 270 described with reference to FIGS. 1 to 10. A number of the sixth posts 274 may be the same as a number of the chips 108 and 109 stacked on the fifth chip 107. An upper surface of the fifth post 264 may be located at the same level as or a different level from an upper surface of the sixth chip 108. The fifth post 264 may have a tapered shape in which a width thereof becomes smaller in a downward direction. According to other embodiments, as illustrated in FIG. 15, the fifth post 264 may have a shape of a column having a constant width. A seed layer 284 may cover a lower surface and an outer circumferential surface of the fifth post 264. The sixth posts 274 may be stacked on the fifth post 264. The sixth posts 274 may be in contact with an upper surface of the fifth post 264, or an upper surface of another sixth post 274 located thereunder. An upper surface of an uppermost sixth post 274 may be exposed at the upper surface of the molding layer 200. Each of the sixth posts 274 may have a tapered shape in which a width thereof becomes smaller toward the fifth post 264.

The third conductive post 255 may penetrate the molding layer 200 to be connected to the chip pad 125 of the sixth chip 108. The third conductive post 255 may include a seventh post 265 and an eighth post 275. The seventh post 265 and the eighth post 275 may respectively correspond to the first post 260 and the second post 270 described with reference to FIGS. 1 to 10. A number of the eighth post 275 may be the same as a number of the chip 109 stacked on the sixth chip 108. An upper surface of the seventh post 265 may be located at the same level as or a different level from an upper surface of the seventh chip 109. The seventh post 265 may have a tapered shape in which a width thereof becomes smaller in a downward direction. According to other embodiments, as illustrated in FIG. 15, the seventh post 265 may have a shape of a column having a constant width. A seed layer 285 may cover a lower surface and an outer circumferential surface of the seventh post 265. The eighth post 275 may be stacked on the seventh post 265. The eighth post 275 may be in contact with the upper surface of the seventh post 265. An upper surface of the eighth post 275 may be exposed at the upper surface of the molding layer 200. The eighth post 275 may have a tapered shape in which a width thereof becomes smaller toward the eighth post 275.

The fourth conductive post 256 may penetrate the molding layer 200 to be connected to the chip pad 125 of the seventh chip 109. The fourth conductive post 256 may include a ninth post 266. The ninth post 266 may correspond to the first post 260 described with reference to FIGS. 1 to 10. The ninth post 266 may have a tapered shape in which a width thereof becomes smaller in a downward direction. According to other embodiments, as illustrated in FIG. 15, the ninth post 266 may have a shape of a column having a constant width. An upper surface of the ninth post 266 may be exposed at the upper surface of the molding layer 200. A seed layer 286 may cover a lower surface and an outer circumferential surface of the ninth post 266.

The second substrate 300 may be disposed on the molding layer 200. The second substrate 300 may be substantially the same as or similar to the second substrate 300 described with reference to FIGS. 1 to 10. For example, the second substrate 300 may include one substrate wiring layer or at least two substrate wiring layers mutually stacked. Each of the substrate wiring layers may include the substrate insulating pattern 310 and the substrate wiring pattern 320 in the substrate insulating pattern 310. The substrate wiring pattern 320 may penetrate the substrate insulating pattern 310 to be connected to an uppermost fourth post 273 of the first conductive post 253, an uppermost sixth post 274 of the second conductive post 254, the eighth post 275 of the third conductive post 255 and the ninth post 266 of the fourth conductive post 256.

FIGS. 16 to 25 are cross-sectional views for describing a method for manufacturing a semiconductor package according to embodiments of the inventive concept.

Referring to FIG. 16, a first carrier substrate 900 may be provided. The first carrier substrate 900 may be an insulating substrate including glass or polymer, or a conductive substrate including metal. Although not shown, a seed layer or adhesive member may be provided on an upper surface of the first carrier substrate 900. For example, the seed layer may include a metal material such as gold (Au). For example, the adhesive member may include an adhesive tape.

A first sacrificial layer 910 may be formed on the first carrier substrate 900. The first sacrificial layer 910 may cover the first carrier substrate 900 or the seed layer formed on the first carrier substrate 900.

First penetration holes TH1 may be formed by patterning the first sacrificial layer 910. For example, after a mask pattern is formed on the first sacrificial layer 910, the first sacrificial layer 910 may be etched by using the mask pattern as an etching mask. Alternatively, the first sacrificial layer 910 may be patterned by performing an exposure and develop process on the first sacrificial layer 910. The first penetration holes TH1 may vertically penetrate the first sacrificial layer 910. The first penetration holes TH1 may expose the upper surface of the first carrier substrate 900. The first penetration holes TH1 may define a region in which a first post 260 and a seed layer 280 of a conductive post 250 are formed in a process to be described later. The first penetration holes TH1 may have a tapered shape in which a width thereof becomes smaller toward the first carrier substrate 900. Alternatively, the first penetration holes TH1 may have a constant width.

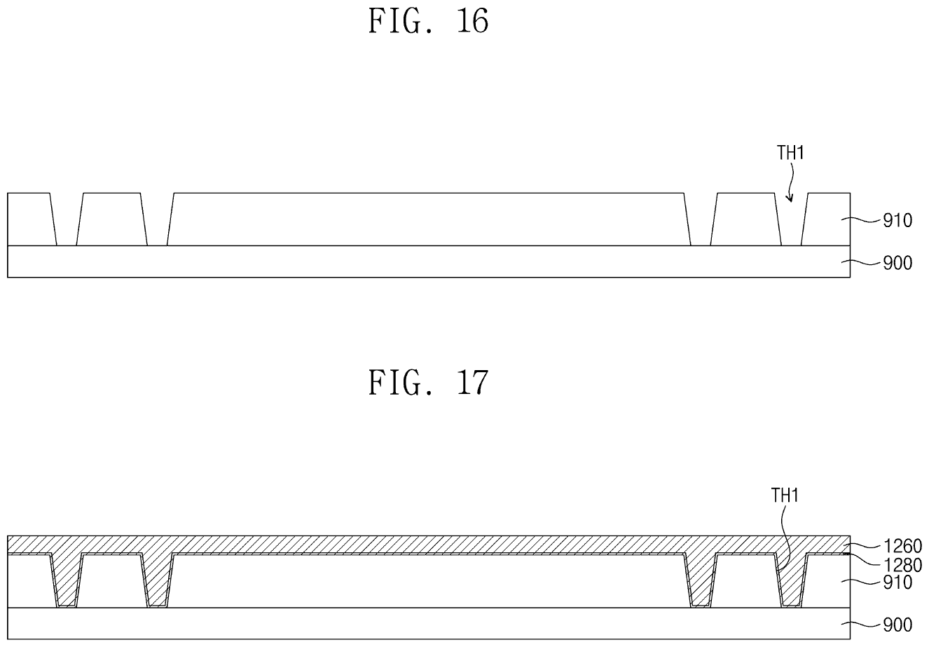

Referring to FIG. 17, a first preliminary seed layer 1280 may be formed on the first sacrificial layer 910. The first preliminary seed layer 1280 may conformally cover an upper surface of the first sacrificial layer 910, an inner side surface of the first penetration holes TH1 and a bottom surface of the first penetration holes TH1 on the first sacrificial layer 910.

A first preliminary conductive layer 1260 may be formed on the first preliminary seed layer 1280. For example, the first preliminary conductive layer 1260 may be formed by performing a plating process using the first preliminary seed layer 1280 as a seed. The first preliminary conductive layer 1260 may cover the upper surface of the first sacrificial layer 910. The first preliminary conductive layer 1260 may fill the first penetration holes TH1.

According to other embodiments, referring to FIG. 18, the first carrier substrate 900 may be provided. A second preliminary seed layer 2280 may be formed on the first carrier substrate 900. The second preliminary seed layer 2280 may cover the upper surface of the first carrier substrate 900. The first sacrificial layer 910 may be formed on the second preliminary seed layer 2280. The first sacrificial layer 910 may cover the second preliminary seed layer 2280. The first penetration holes TH1 may be formed by patterning the first sacrificial layer 910. The first penetration holes TH1 may vertically penetrate the first sacrificial layer 910. The first penetration holes TH1 may expose an upper surface of the second preliminary seed layer 2280.

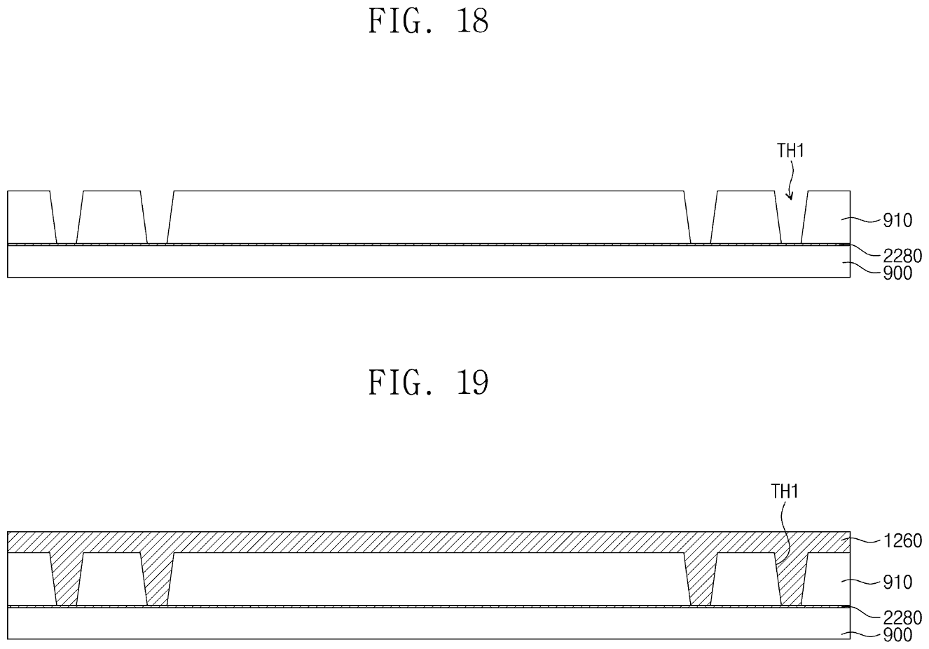

Referring to FIG. 19, the first preliminary conductive layer 1260 may be formed on the first sacrificial layer 910. For example, the first preliminary conductive layer 1260 may be formed by performing a plating process using the second preliminary seed layer 2280 exposed by the first penetration holes TH1 as a seed. The first preliminary conductive layer 1260 may cover the upper surface of the first sacrificial layer 910. The first preliminary conductive layer 1260 may fill the first penetration holes TH1. In this case, the semiconductor package described with reference to FIG. 3 may be manufactured. Hereinafter, the method will be continuously described on the basis of embodiments of FIGS. 16 and 17.

Referring to FIG. 20, a thinning process may be performed on the first preliminary conductive layer 1260. The thinning process may include a chemical mechanical polishing (CMP) process, a grinding process, or the like. An upper surface of the first preliminary conductive layer 1260 may be lowered by the thinning process. The thinning process may be performed until an upper surface of the first preliminary seed layer 1280 is exposed.

The thinning process may be continuously performed on the first preliminary seed layer 1280 to lower the upper surface of the first preliminary seed layer 1280. The thinning process may be performed until the upper surface of the first sacrificial layer 910 is exposed.

The first posts 260 and the seed layers 280 may be formed in the first penetration holes TH1 by the thinning process. Upper surfaces of the first posts 260 and upper surfaces of the seed layers 280 may be coplanar with the upper surface of the first sacrificial layer 910.

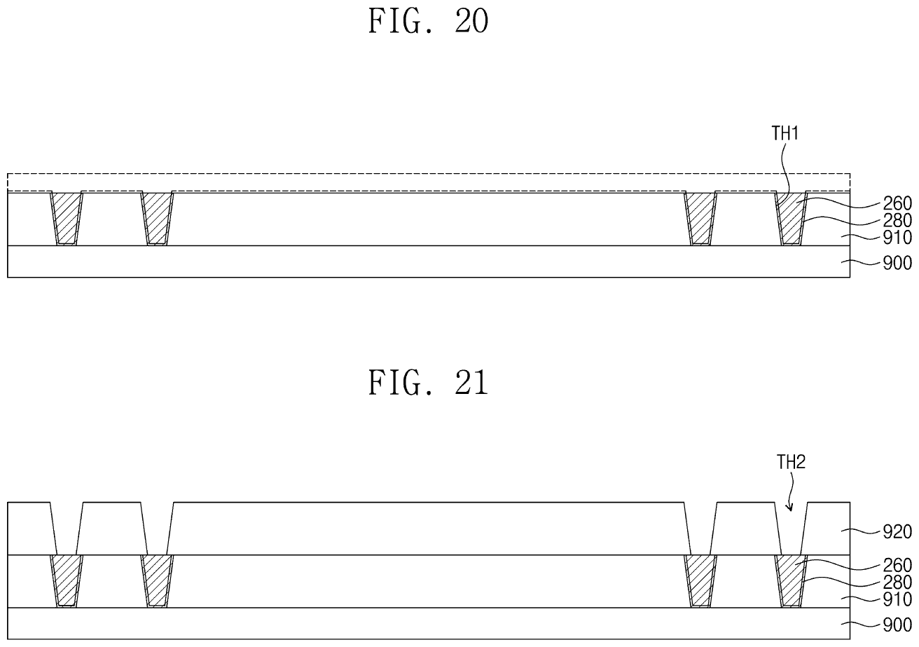

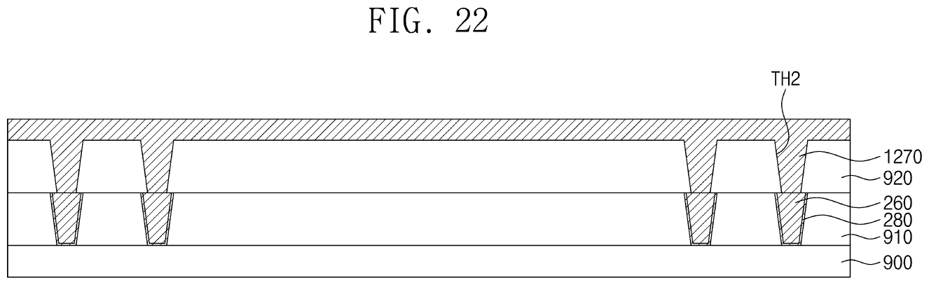

Referring to FIG. 21, a second sacrificial layer 920 may be formed on the first sacrificial layer 910. The second sacrificial layer 920 may cover the first sacrificial layer 910, the first posts 260 and the seed layers 280.

Second penetration holes TH2 may be formed by patterning the second sacrificial layer 920. For example, after a mask pattern is formed on the second sacrificial layer 920, the second sacrificial layer 920 may be etched using the mask pattern as an etching mask. Alternatively, the second sacrificial layer 920 may be pattern by performing an exposure and develop process on the second sacrificial layer 920. The second penetration holes TH2 may vertically penetrate the second sacrificial layer 920. The second penetration holes TH2 may expose the upper surfaces of the first posts 260. The second penetration holes TH2 may define a region in which the second post 270 of the conductive post 250 is formed in a process to be described later. The second penetration holes TH2 may have a tapered shape in which a width thereof becomes smaller toward the first carrier substrate 900.

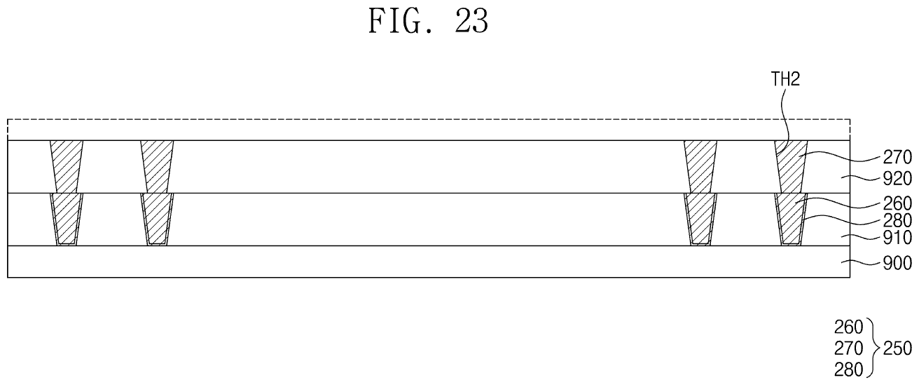

Referring to FIG. 22, a second preliminary conductive layer 1270 may be formed on the second sacrificial layer 920. For example, the second preliminary conductive layer 1270 may be formed by performing a plating process using the first posts 260 exposed by the second penetration holes TH2 as seeds. The second preliminary conductive layer 1270 may cover an upper surface of the second sacrificial layer 920. The second preliminary conductive layer 1270 may fill the second penetration holes TH2.

Referring to FIG. 23, a thinning process may be performed on the second preliminary conductive layer 1270. The thinning process may include a chemical mechanical polishing (CMP) process, a grinding process, or the like. An upper surface of the second preliminary conductive layer 1270 may be lowered by the thinning process. The thinning process may be performed until the upper surface of the second sacrificial layer 920 is exposed.

Second posts 270 may be formed in the second penetration holes TH2 by the thinning process. An upper surface of the second post 270 may be coplanar with the upper surface of the second sacrificial layer 920.

The first posts 260, the second posts 270 and the seed layers 280 may constitute the conductive post 250.

Widths of penetration holes may be required so as to be at least a certain size according to depths of the penetration holes in a process of forming the penetration holes for forming a conductive post.

According to embodiments of the inventive concept, since the conductive posts 250 are formed as a multiple step structure including the first posts 260 and the second posts 270, the conductive posts 250 having a great aspect ratio may be formed. More specifically, since the posts 260 and 270 having small widths are each formed and stacked, the conductive posts 250 simultaneously having small widths and great heights may be formed. Accordingly, an area occupied by the conductive posts 250 may be small, and the miniaturized semiconductor package with improved integration may be provided.

In addition, the first posts 260, located at a lower end, of the posts 260 and 270 that constitute the conductive posts 250 may serve as seeds for forming the second post 270 located at an upper end. That is, a process for forming the second posts 270 may be simpler, and the method for manufacturing a semiconductor package with a simpler manufacturing process may be provided.

In addition, since the first posts 260 are formed such that the upper surfaces thereof are wider than lower surfaces thereof, the second penetration holes TH2 for forming the second posts 270 may be easy to align on the first posts 260. That is, the method for manufacturing a semiconductor package with less defect occurrence may be provided.

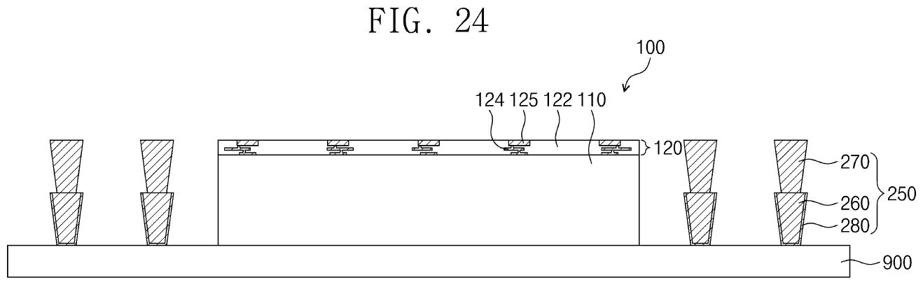

Referring to FIG. 24, the first sacrificial layer 910 and the second sacrificial layer 920 may be removed.

A semiconductor chip 100 may be attached onto the first carrier substrate 900. The semiconductor chip 100 may be substantially the same as or similar to the semiconductor chip 100 described with reference to FIG. 1. The semiconductor chip 100 may be disposed in a face-up form. That is, a rear surface (that is, an inactive surface) of the semiconductor chip 100 may face the first carrier substrate 900, and chip pads 125 of the semiconductor chip 100 may be disposed so as to be opposed to the first carrier substrate 900.

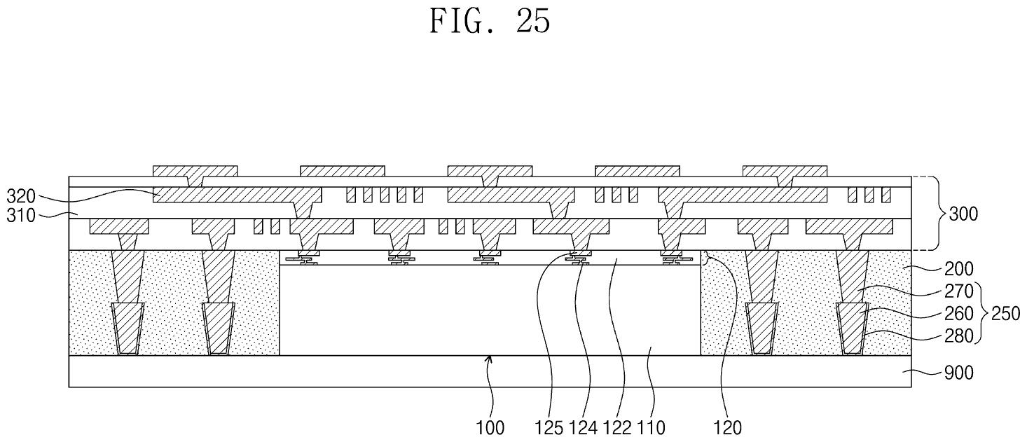

Referring to FIG. 25, a molding layer 200 may be formed on the first carrier substrate 900. For example, a molding material may be applied on the upper surface of the first carrier substrate 900 so as to bury the semiconductor chip 100 and the conductive posts 250, and the molding material may be cured to form the molding layer 200. For example, the molding material may include an epoxy molding compound (EMC).

A thinning process may be performed on the molding layer 200. The thinning process may include a chemical mechanical polishing (CMP) process, a grinding process, or the like. An upper surface of the molding layer 200 may be lowered by the thinning process. The thinning process may be performed until upper surfaces of the conductive posts 250 and an upper surface of the semiconductor chip 100 are exposed. When the upper surfaces of the conductive posts 250 are provided at a higher level than the upper surface of the semiconductor chip 100, upper portions of the conductive posts 250 may be partially removed during the thinning process.

A substrate 300 may be formed on the molding layer 200. For example, an insulating layer may be formed by depositing an insulating material on the molding layer 200. A substrate insulating pattern 310 may be formed by patterning the insulating layer so as to expose the conductive posts 250 and the chip pads 125. A conductive layer may be formed on the substrate insulating pattern 310. A substrate wiring pattern 320 may be formed by patterning the conductive layer. One substrate wiring layer may be formed like the above. The substrate 300 may be formed by repeatedly performing a process of forming the substrate wiring layer.

Referring back to FIG. 1, the first carrier substrate 900 may be removed. Accordingly, a lower surface of the molding layer 200, a lower surface of the semiconductor chip 100 and lower surfaces of the conductive posts 250 may be exposed.

A protective layer 410 may be formed on the lower surface of the molding layer 200. For example, the protective layer 410 may be formed by depositing or applying an insulating material covering the lower surface of the molding layer 200, the lower surface of the semiconductor chip 100 and the lower surfaces of the conductive posts 250. Openings exposing the lower surfaces of the conductive posts 250 may be formed by patterning the protective layer 410.

Second external terminals 420 may be provided under the protective layer 410. The second external terminals 420 may be connected to a lower surface of the seed layer 280 of the conductive post 250 exposed by the protective layer 410.

First external terminals 302 may be provided on upper surfaces of the substrate pads exposed at an upper surface of the second substrate 300.

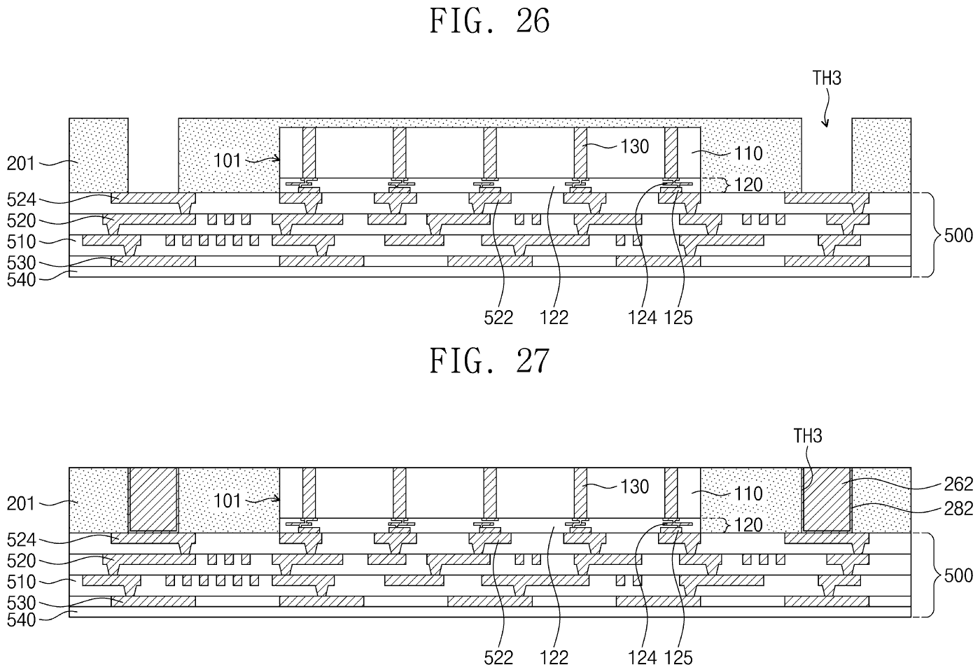

FIGS. 26 to 31 are cross-sectional views for describing a method for manufacturing a semiconductor package according to embodiments of the inventive concept.

Referring to FIG. 26, a first substrate 500 may be formed. For example, a carrier substrate may be provided. A substrate protective layer 540 may be provided on the carrier substrate. The substrate protective layer 540 may include insulating polymer or photosensitive polymer. External pads 530 may be formed inside the substrate protective layer 540. For example, the external pads 530 that fill openings may be formed by forming the openings for forming the external pads 530 by patterning the substrate protective layer 540, conformally forming a seed layer in the openings, and performing a plating process using the seed layer as a seed. A first substrate insulating pattern 510 may be formed on the substrate protective layer 540. The first substrate insulating pattern 510 may be formed in a coating process such as spin coating or slit coating. The first substrate insulating pattern 510 may include photosensitive polymer. Openings may be formed in the first substrate insulating pattern 510. For example, the openings may be formed by patterning the first substrate insulating pattern 510. The openings may have a cross-section having a T shape. The openings may expose the external pads 530. A first substrate wiring pattern 520 may be formed. For example, after a barrier layer and a conductive layer are formed on the first substrate insulating pattern 510 so as to fill the openings, the first substrate wiring pattern 520 may be formed by performing a planarization process on the barrier layer and the conductive layer. Like the above, a first substrate wiring layer having the first substrate insulating pattern 510 and the first substrate wiring pattern 520 may be formed. The first substrate 500 on which the first substrate wiring layer is stacked may be formed by repeating a process of forming the first substrate wiring layer. The first substrate wiring pattern 520 of an uppermost first substrate wiring layer may correspond to first substrate pads 522 and second substrate pads 524 of the first substrate 500.

A first chip 101 may be provided. A configuration of the first chip 101 may be the same as or similar to what is described with reference to FIG. 13. For example, the first chip 101 may have a chip base layer 110, a chip circuit layer 120 covering the chip base layer 110, and chip vias 130 vertically penetrating the chip base layer 110 to be connected to the chip circuit layer 120.

The first chip 101 may be adhered onto the first substrate 500. The first chip 101 may be aligned on the first substrate 500 such that chip pads 125 of the first chip 101 are located on the first substrate pads 522 of the first substrate 500. The first chip 101 may be disposed on the first substrate 500 such that the chip pads 125 are in contact with the first substrate pads 522. A heat treatment process may be performed on the first chip 101. The chip pads 125 and the first substrate pads 522 may be adhered to each other by the heat treatment process. For example, the chip pads 125 and the first substrate pads 522 may be coupled to each other to be integrally formed. The chip pads 125 and the first substrate pads 522 may be naturally coupled to each other. Specifically, the chip pads 125 and the first substrate pads 522 may be composed of the same material, and the chip pads 125 and the first substrate pads 522 may be coupled to each other by an intermetallic hybrid bonding on boundary surfaces of the chip pads 125 and the first substrate pads 522 in contact with each other by surface activation.

A third molding layer 201 may be formed on the first substrate 500. The third molding layer 201 may cover the first chip 101. Third penetration holes TH3 may be formed by patterning the third molding layer 201. The third penetration holes TH3 may vertically penetrate the third molding layer 201 to expose upper surfaces of the second substrate pads 524 of the first substrate 500. The third penetration holes TH3 may have a shape of a column having a constant width.

Referring to FIG. 27, first post 262 and seed layer 282 may be formed in the third penetration holes TH3. For example, a preliminary seed layer conformally covering an upper surface of the third molding layer 201, inner side surfaces of the third penetration holes TH3, and a bottom surface of the third penetration holes TH3 may be formed on the third molding layer 201. A preliminary conductive layer that fills the third penetration holes TH3 may be formed by performing a plating process using the preliminary seed layer as a seed. Thereafter, the upper surface of the third molding layer 201 may be exposed by performing a thinning process on the preliminary conductive layer and the preliminary seed layer. The first posts 262 and the seed layers 282 may be formed in the third penetration holes TH3 by the thinning process. An upper surface of the first chip 101 may be exposed at the upper surface of the third molding layer 201 by partially removing the third molding layer 201 located on the first chip 101 during the thinning process.

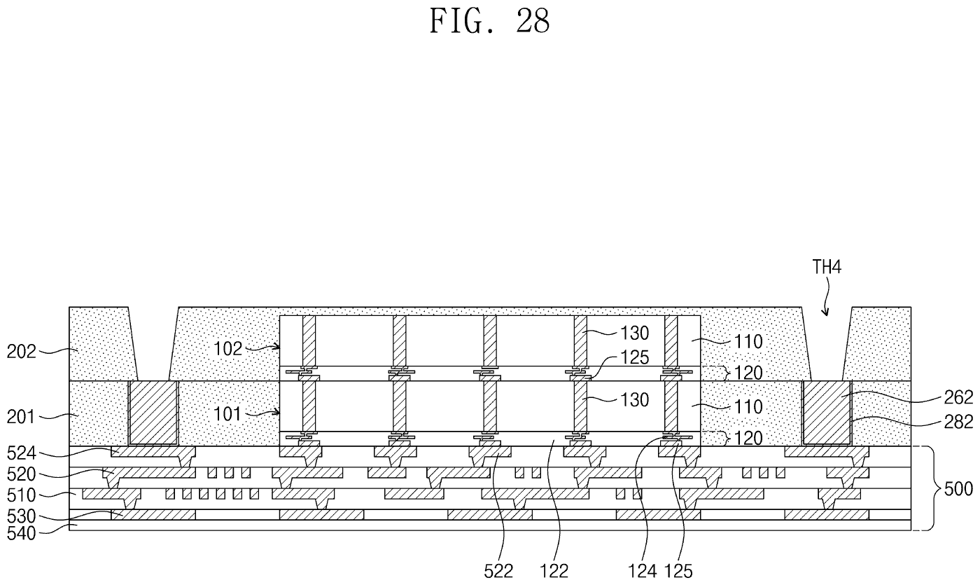

Referring to FIG. 28, a second chip 102 may be provided. A configuration of the second chip 102 may be the same as or similar to what is described with reference to FIG. 13. For example, the second chip 102 may have the chip base layer 110, the chip circuit layer 120 covering the chip base layer 110, and the chip vias 130 vertically penetrating the chip base layer 110 to be connected to the chip circuit layer 120.

The second chip 102 may be adhered onto the first chip 101. A process of adhering the first chip 101 and the second chip 102 may be substantially the same as or similar to the process of adhering the first chip 101 and the first substrate 500 described with reference to FIG. 26. For example, the chip pads 125 of the second chip 102 may be in contact with the chip vias 130 of the first chip 101. The chip pads 125 and the chip vias 130 may be adhered to each other by performing a heat treatment on the second chip 102. The chip pads 125 and the chip vias 130 may be naturally coupled to each other.

A fourth molding layer 202 may be formed on the third molding layer 201. The fourth molding layer 202 may cover the second chip 102. Fourth penetration holes TH4 may be formed by patterning the fourth molding layer 202. The fourth penetration holes TH4 may vertically penetrate the fourth molding layer 202 to expose upper surfaces of the first posts 262. The fourth penetration holes TH4 may have a tapered shape in which a width thereof becomes smaller toward the first posts 262.

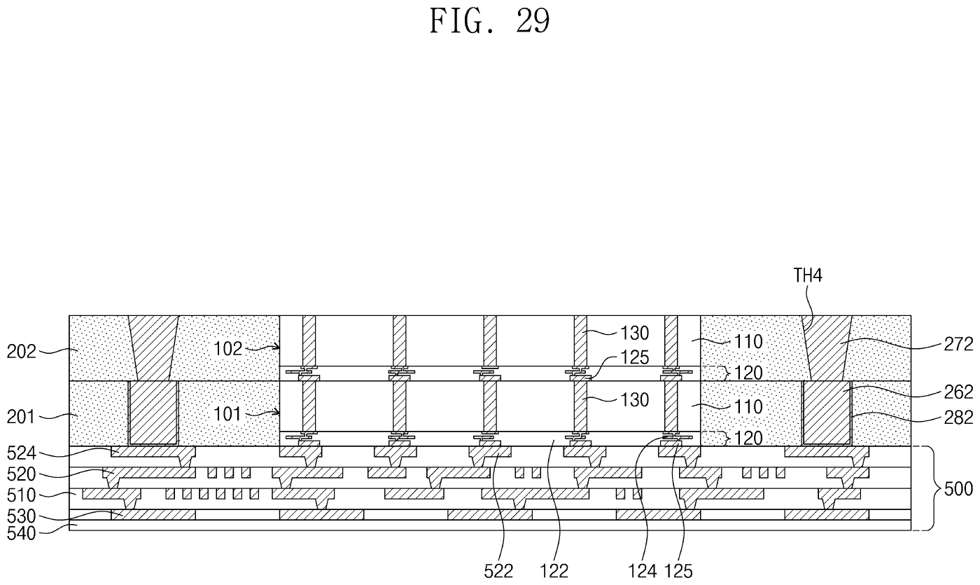

Referring to FIG. 29, second posts 272 may be formed in the fourth penetration holes TH4. For example, a preliminary conductive layer that fills the fourth penetration holes TH4 may be formed by performing a plating process using the first posts 262 exposed by the fourth penetration holes TH4 as seeds. Thereafter, an upper surface of the fourth molding layer 202 may be exposed by performing a thinning process on the preliminary conductive layer. The second posts 272 may be formed in the fourth penetration holes TH4 by the thinning process. An upper surface of the second chip 102 may be exposed at the upper surface of the fourth molding layer 202 by partially removing the fourth molding layer 202 located on the second chip 102 during the thinning process.

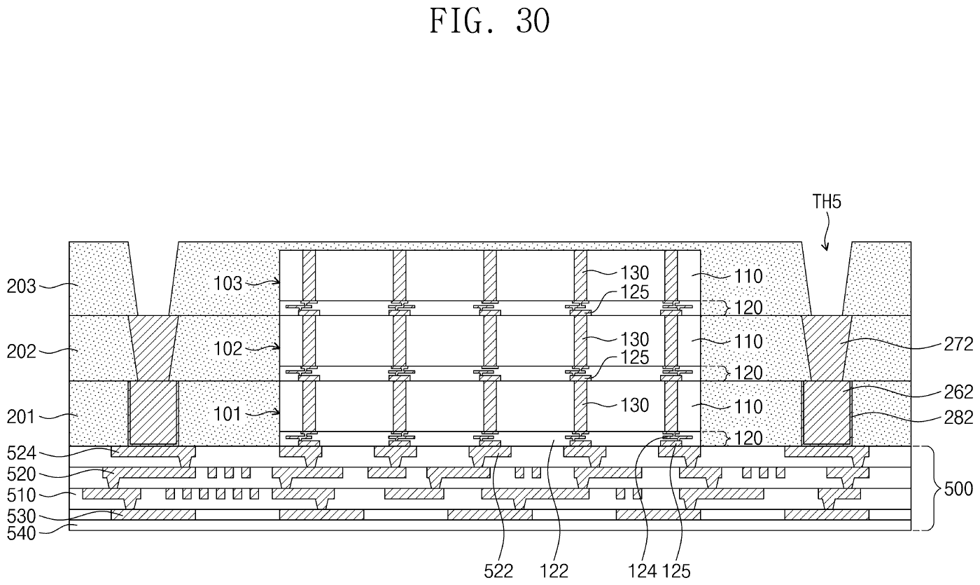

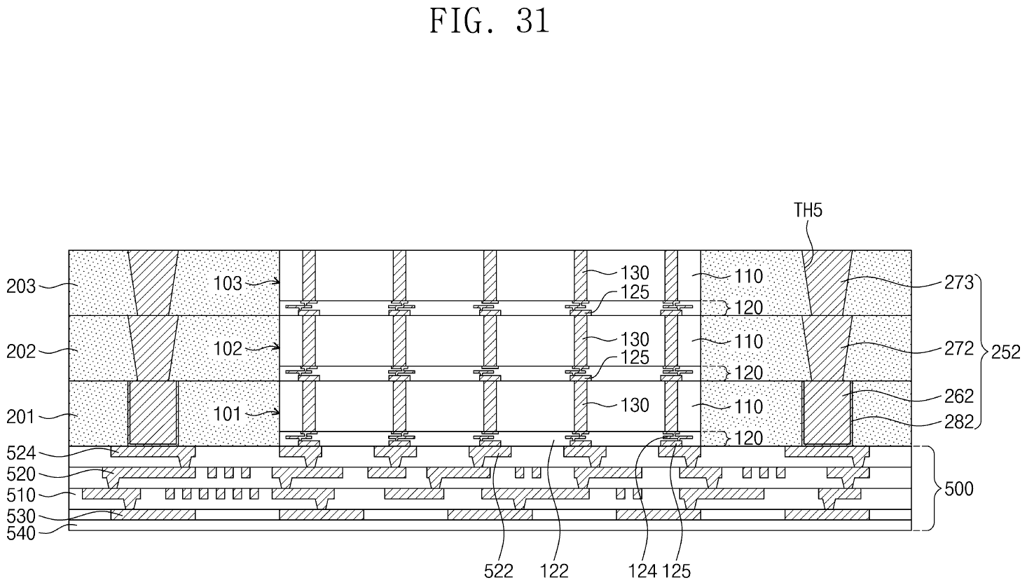

Referring to FIG. 30, a third chip 103 may be provided. A configuration of the third chip 103 may be the same as or similar to what is described with reference to FIG. 13. For example, the third chip 103 may have the chip base layer 110, the chip circuit layer 120 covering the chip base layer 110, and the chip vias 130 vertically penetrating the chip base layer 110 to be connected to the chip circuit layer 120.

The third chip 103 may be adhered onto the second chip 102. A process of adhering the third chip 103 and the second chip 102 may be substantially the same as or similar to the process of adhering the first chip 101 and the second chip 102. For example, the chip pads 125 of the third chip 103 may be in contact with the chip vias 130 of the second chip 102. The chip pads 125 and the chip vias 130 may be adhered to each other by performing a heat treatment process on the third chip 103. The chip pads 125 and the chip vias 130 may be naturally coupled to each other.

A fifth molding layer 203 may be formed on the fourth molding layer 202. The fifth molding layer 203 may cover the third chip 103. Fifth penetration holes TH5 may be formed by patterning the fifth molding layer 203. The fifth penetration holes TH5 may vertically penetrate the fifth molding layer 203 to expose upper surfaces of the second posts 272. The fifth penetration holes TH5 may have a tapered shape in which a width thereof becomes smaller toward the first posts 262.

Referring to FIG. 29, other second posts 272 may be formed in the fifth penetration holes TH5. For example, a preliminary conductive layer that fills the fifth penetration holes TH5 may be formed by performing a plating process using the second posts 272 exposed by the fifth penetration holes TH5 as seeds. Thereafter, an upper surface of the fifth molding layer 203 may be exposed by performing a thinning process on the preliminary conductive layer. The second posts 272 may be formed in the fifth penetration holes TH5 by the thinning process. An upper surface of the third chip 103 may be exposed at the upper surface of the fifth molding layer 203 by partially removing the fifth molding layer 203 located on the third chip 103 during the thinning process. The first post 262, the second posts 272 stacked on the first post 262 and the seed layer 282 may constitute the conductive post 252.

Referring back to FIG. 13, a second substrate 300 may be formed on the fifth molding layer 203. For example, an insulating layer may be formed by depositing an insulating material on the fifth molding layer 203. The substrate insulating pattern 310 may be formed by patterning the insulating layer so as to expose the conductive posts 252. A conductive layer may be formed on the substrate insulating pattern 310. The substrate wiring pattern 320 may be formed by patterning the conductive layer. One substrate wiring layer may be formed like the above. The second substrate 300 may be formed by repeatedly performing a process of forming the substrate wiring layer.

Openings exposing lower surfaces of the external pads 530 may be formed by patterning the substrate protective layer 540. External terminals 550 may be provided under the substrate protective layer 540. The external terminals 550 may be connected to the lower surfaces of the external pads 530 exposed at the substrate protective layer 540.

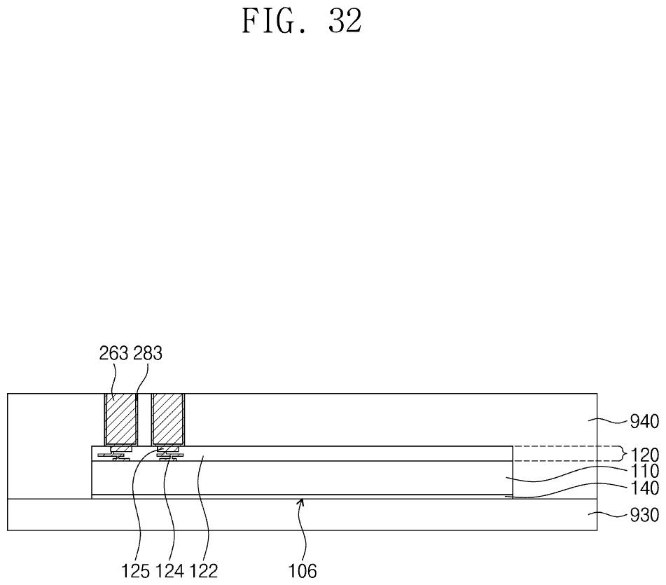

FIGS. 32 to 37 are cross-sectional views for describing a method for manufacturing a semiconductor package according to embodiments of the inventive concept.

Referring to FIG. 32, a second carrier substrate 930 may be provided. The second carrier substrate 930 may be an insulating substrate including glass or polymer, or a conductive substrate including metal.

A fourth chip 106 may be attached onto the second carrier substrate 930. The fourth chip 106 may be substantially the same as or similar to what is described with reference to FIGS. 14 and 15. The fourth chip 106 may be attached onto the second carrier substrate 930 using adhesive layers 140. The fourth chip 106 may be disposed in a face-up form. That is, an inactive surface of the fourth chip 106 may face the second carrier substrate 930, and chip pads 125 of the fourth chip 106 may be disposed to oppose the second carrier substrate 930.

A third sacrificial layer 940 may be formed on the second carrier substrate 930. The third sacrificial layer 940 may cover the fourth chip 106 on the second carrier substrate 930. Penetration holes may be formed by patterning the third sacrificial layer 940. The penetration holes may vertically penetrate the third sacrificial layer 940 to expose the chip pads 125 of the fourth chip 106. The penetration holes may have a shape of a column having a constant width. Third posts 263 and seed layers 283 may be formed in the penetration holes. For example, a preliminary seed layer conformally covering inner side surfaces and bottom surfaces of the penetration holes may be formed, and a preliminary conductive layer that fills the penetration holes may be formed by performing a plating process using the preliminary seed layer as a seed. Thereafter, the third post 263 and the seed layers 283 may be formed in the penetration holes by performing a thinning process on the preliminary conductive layer and the preliminary seed layer.

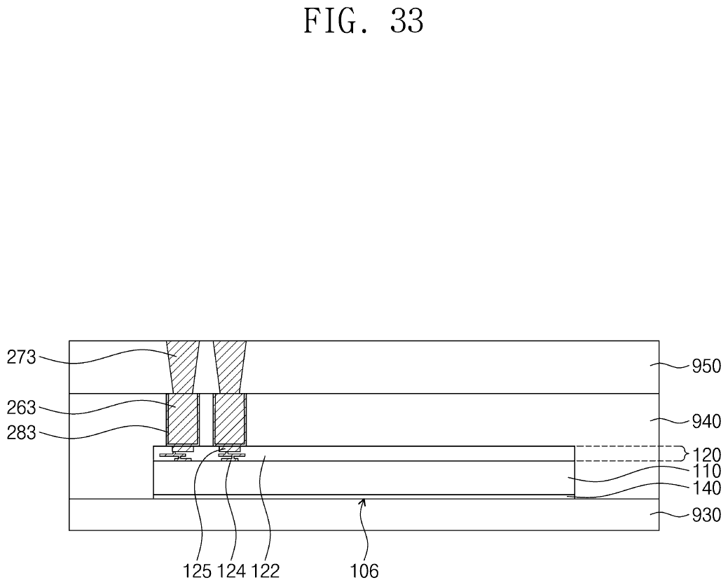

Referring to FIG. 33, a fourth sacrificial layer 950 may be formed on the third sacrificial layer 940. Penetration holes may be formed by patterning the fourth sacrificial layer 950. The penetration holes may vertically penetrate the fourth sacrificial layer 950 to expose the third posts 263. The penetration holes may have a tapered shape in which a width thereof becomes smaller toward the third posts 263. Fourth posts 273 may be formed in the penetration holes. For example, a preliminary conductive layer that fills the penetration holes may be formed by performing a plating process using the third posts 263 exposed by the penetration hole as seeds. Thereafter, the fourth posts 273 may be formed in the penetration holes by performing a thinning process on the preliminary conductive layer.

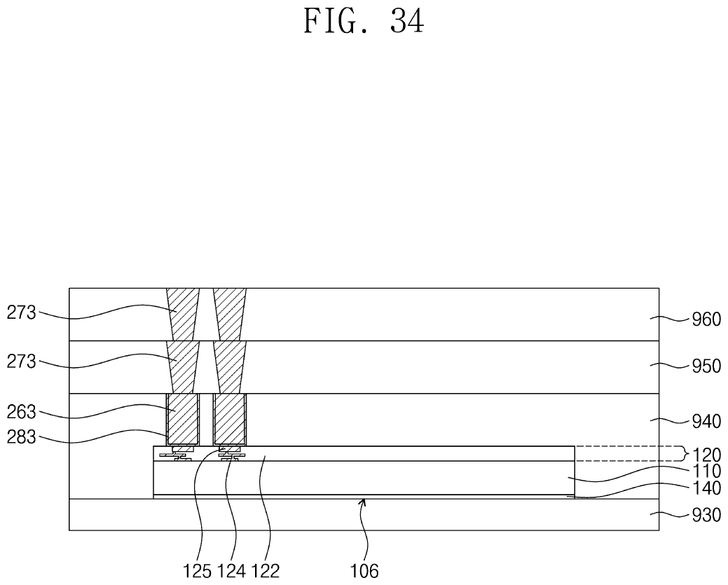

Referring to FIG. 34, a fifth sacrificial layer 960 may be formed on the fourth sacrificial layer 950. Penetration holes exposing the fourth posts 273 in the fourth sacrificial layer 950 may be formed by patterning the fifth sacrificial layer 960. The penetration holes may have a tapered shape in which a width thereof becomes smaller toward the third posts 263. Other fourth posts 273 stacked on the fourth posts 273 in the fourth sacrificial layer 950 may be formed in the penetration holes. For example, a preliminary conductive layer that fills the penetration holes may be formed by performing a plating process using the fourth posts 273 exposed by the penetration holes as seeds. Thereafter, the fourth posts 273 may be formed in the penetration holes by performing a thinning process on the preliminary conductive layer.

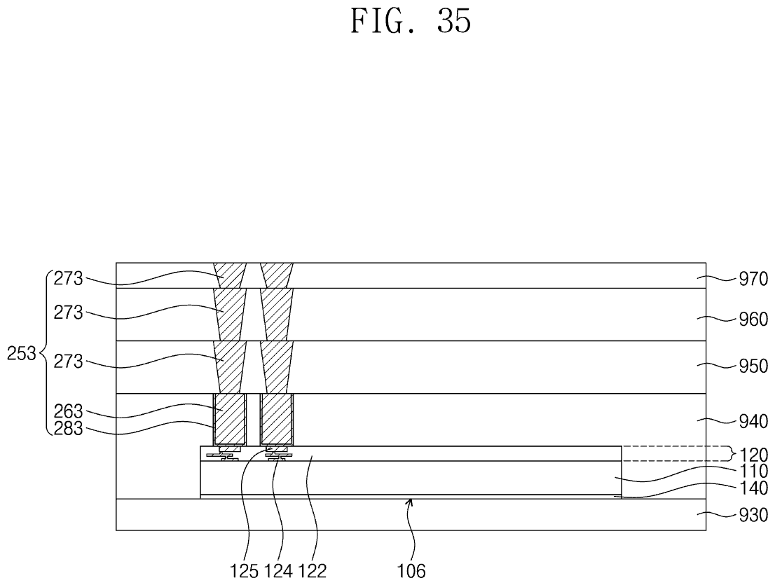

Referring to FIG. 35, a sixth sacrificial layer 970 may be formed on the fifth sacrificial layer 960. Penetration holes exposing the fourth posts 273 in the fifth sacrificial layer 960 may be formed by patterning the sixth sacrificial layer 970. The penetration holes may have a tapered shape in which a width thereof becomes smaller toward the third posts 263. Other fourth posts 273 stacked on the fourth posts 273 in the fifth sacrificial layer 960 may be formed in the penetration holes. For example, a preliminary conductive layer that fills the penetration holes may be formed by performing a plating process using the fourth posts 273 exposed by the penetration holes as seeds. Thereafter, the fourth posts 273 may be formed in the penetration holes by performing a thinning process on the preliminary conductive layer.

The third posts 263, and the fourth posts 273 and the seed layers 283 stacked on the third posts 263 may constitute first conductive posts 253. The fourth chip 106 and the first conductive posts 253 connected to the fourth chip 106 may be formed like the above.

Thereafter, the third sacrificial layer 940, the fourth sacrificial layer 950, the fifth sacrificial layer 960 and the sixth sacrificial layer 970 may be removed.

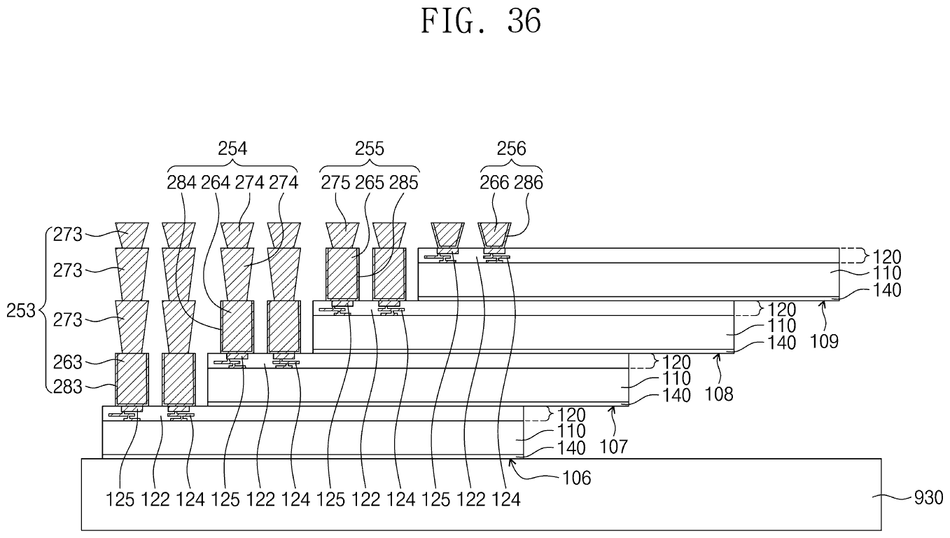

Referring to FIG. 36, a fifth chip 107 and second conductive posts 254 connected to the fifth chip 107 may be formed. Forming the fifth chip 107 and the second conductive posts 254 may be substantially the same as or similar to a process of forming the fourth chip 106 and the first conductive posts 253 described with reference to FIGS. 32 to 35. Fifth posts 264 connected to the fifth chip 107 and sixth posts 274 and seed layers 284 stacked on the fifth post 264 may constitute the second conductive posts 254. A number of the sixth posts 274 of each of the second conductive posts 254 may be one smaller than a number of the fourth posts 273 stacked on each of the first conductive posts 253.

A sixth chip 108 and third conductive posts 255 connected to the sixth chip 108 may be formed. Forming the sixth chip 108 and the third conductive posts 255 may be substantially the same as or similar to the process of forming the fourth chip 106 and the first conductive post 253 described with reference to FIGS. 32 to 35. Seventh posts 265 connected to the sixth chip 108, and eighth posts 275 and seed layers 285 stacked on the seventh post 265 may constitute the third conductive posts 255. A number of the eighth posts 275 of each of the third conductive posts 255 may be one smaller than a number of the sixth posts 274 stacked on each of the second conductive posts 254.

A seventh chip 109 and fourth conductive posts 256 connected to the seventh chip 109 may be formed. Forming the seventh chip 109 and the fourth conductive posts 256 may be substantially the same as or similar to the process of forming the fourth chip 106 and the first conductive posts 253 described with reference to FIGS. 32 to 35. The ninth posts 266 and the seed layers 285 connected to the seventh chip 109 may constitute the fourth conductive post 256.

The fifth to seventh semiconductor chips 107, 108 and 109 may stacked on the fourth chip 106. The fifth chip 107 may be attached onto the fourth chip 106 using an adhesive layer 140, the sixth chip 108 may be attached onto the fifth chip 107 using the adhesive layer 140, and the seventh chip 109 may be attached onto the sixth chip 108 using the adhesive layer 140. The fourth to seventh chips 106, 107, 108 and 109 may be stacked to be shifted from each other in a direction parallel to an upper surface of the second carrier substrate 930 such that the fifth chip 107 is spaced apart from the first conductive posts 253, the sixth chip 108 is spaced apart from the second conductive posts 254, and the seventh chip 109 is spaced apart from the third conductive posts 255.

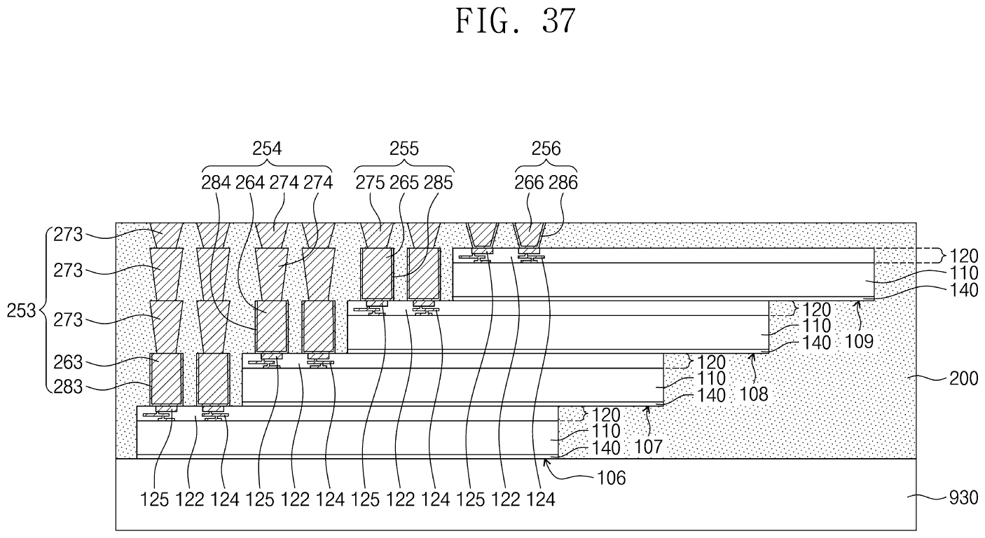

Referring to FIG. 37, a molding layer 200 may be formed on the second carrier substrate 930. The molding layer 200 may cover the fourth to seventh chips 106, 107, 108 and 109 and the first to fourth conductive posts 253, 254, 255 and 256. Thereafter, upper surfaces of the first to fourth conductive posts 253, 254, 255 and 256 may be exposed by performing a thinning process on the molding layer 200.

Referring back to FIG. 15, a substrate 300 may be formed on the molding layer 200. For example, an insulating layer may be formed by depositing an insulating material on the molding layer 200. A substrate insulating pattern 310 may be formed by patterning the insulating layer so as to expose the first to fourth conductive posts 253, 254, 255 and 256. A conductive layer may be formed on the substrate insulating pattern 310. A substrate wiring pattern 320 may be formed by patterning the conductive layer. One substrate wiring layer may be formed like the above. The second substrate 300 may be formed by repeatedly performing the process of forming the substrate wiring layer.

Thereafter, the second carrier substrate 930 may be removed.

In a semiconductor package according to embodiments of the inventive concept, a conductive post having a great height and a great aspect ratio may be provided. Accordingly, an area occupied by the conductive posts may be small, and the miniaturized semiconductor package with improved integration may be provided. In addition, a structural defect in which a second post is misaligned with a first post during formation of the second post may not occur. That is, the semiconductor package with improved structural stability, and without contact failure between the first and second posts may be provided.

In a method for manufacturing a semiconductor package according to embodiments of the inventive concept, a process for forming the second posts may be simpler, and a manufacturing process may be simpler. In addition, second penetration holes for forming the second posts may be easily aligned on the first posts. That is, the method for manufacturing a semiconductor package with less defect occurrence may be provided.

What is claimed is:

1. A semiconductor package comprising:
a package substrate;
a first semiconductor chip on the package substrate;
a molding layer surrounding the first semiconductor chip on the package substrate;
a conductive post extending through the molding layer on one side of the first semiconductor chip and connected to the package substrate; and
external terminals on a lower surface of the package substrate,
wherein the conductive post comprises:
a first post; and
a second past on the first post and connected to a first upper surface of the first post,
wherein the first post has a columnar shape, and
wherein the second post has a tapered shape in which a width thereof decreases toward the first post.

2. The semiconductor package of claim 1, wherein the conductive post further comprises a seed layer on a first lower surface of the first post.

3. The semiconductor package of claim 2, wherein the seed layer extends from the first lower surface of the first post onto an outer circumferential surface of the first post.

4. The semiconductor package of claim 1, wherein the second post comprises a second lower surface and an opposite second upper surface, and
wherein a width or a diameter of the second upper surface is about 1.5 times to about times a width or a diameter of the second lower surface.

5. The semiconductor package of claim 1, wherein a second lower surface of the second post is in contact with the first upper surface of the first post, and an outer circumferential surface of the second post is in contact with the molding layer.

6. The semiconductor package of claim 1, wherein the molding layer comprises:
a first molding layer; and
a second molding layer on the first molding layer, and
wherein an interface between the first molding layer and the second molding layer is coplanar with an interface between the first post and the second post.

7. The semiconductor package of claim 1, further comprising a second semiconductor chip on the first semiconductor chip,
wherein the second semiconductor chip is in contact with an upper surface of the first semiconductor chip,
wherein the molding layer surrounds the first semiconductor chip and the second semiconductor chip, and
wherein an interface between the first post and the second post is coplanar with an interface between the first semiconductor chip and the second semiconductor chip.

8. The semiconductor package of claim 1, wherein the first post is connected to a substrate pad of the package substrate.

9. The semiconductor package of claim 1, wherein a width of a second lower surface of the second post is about 1 μm to about 5 μm, and
wherein a width of a second upper surface of the second post is about 10 μm to about 50 μm.

10. A semiconductor package comprising:
a first semiconductor chip;
a molding layer surrounding the first semiconductor chip;
a first conductive post extending through the molding layer on one side of the first semiconductor chip; and
a substrate on the molding layer and the first semiconductor chip,
wherein the first conductive post comprises:
a first post;
a second post on the first post and in contact with a first upper surface of the first post; and
a first seed layer on a first lower surface of the first post, and
wherein the second post has a tapered shape in which a width thereof decreases toward the first post.

11. The semiconductor package of claim 10, wherein the first post has a shape of a column with a constant width, or
wherein the first post has a tapered shape in which a width thereof decreases in a direction away from the second post.

12. The semiconductor package of claim 10, wherein the first seed layer extends from the first lower surface of the first post onto an outer circumferential surface of the first post.

13. The semiconductor package of claim 10, wherein the second post comprises a second lower surface and an opposite second upper surface, and
wherein a width or a diameter of the second upper surface is about 1.5μ to about 10 times a width or a diameter of the second lower surface.

14. The semiconductor package of claim 10, wherein a second lower surface of the second post is in contact with the first upper surface of the first post, and an outer circumferential surface of the second post is in contact with the molding layer.

15. The semiconductor package of claim 10, further comprising:
a second semiconductor chip on the first semiconductor chip; and
a second conductive post extending through the molding layer on one side of the second semiconductor chip,
wherein the first semiconductor chip comprises a chip pad on a first upper surface of the first semiconductor chip,
wherein the second conductive post is connected to the chip pad,
wherein the second conductive post comprises:
a third post;
a fourth post on the third post and in contact with a third upper surface of the third post; and
a first seed layer on a third lower surface of the third post, and
wherein the fourth post has a tapered shape in which a width thereof decreases toward the third post.

16. The semiconductor package of claim 15, wherein the first post has a shape of a column with a constant width, and
wherein the third post has a shape of a column with a constant width.

17. The semiconductor package of claim 10, wherein the molding layer comprises:
a first molding layer; and
a second molding layer on the first molding layer, and
wherein an interface between the first molding layer and the second molding layer is coplanar with an interface between the first post and the second post.

18. The semiconductor package of claim 10, wherein a wiring pattern of the substrate is connected to a second upper surface of the second post.

19. The semiconductor package of claim 10, wherein an active surface of the first semiconductor chip faces the substrate.

20. A semiconductor package comprising:
a semiconductor chip;
a molding layer surrounding the semiconductor chip;
a conductive post extending through the molding layer on one side of the semiconductor chip; and
a substrate on the molding layer and the semiconductor chip and having a substrate wiring pattern connected to the conductive post and the semiconductor chip,
wherein the conductive post comprises:
a first post;
a seed layer on a lower surface and an outer circumferential surface of the first post; and
a second post on the first post and in contact with a first upper surface of the first post,
wherein a width of the first post is greater than a width of the second post on a contact surface of the first post and the second post,
wherein a width of a lower surface of the second post is smaller than a width of an upper surface of the second post, and
wherein an outer circumferential surface of the second post is in contact with the molding layer.
